(19) United States
(12) Patent Application Publication
(10) Pub. No.: US 2024/0178176 A1
(43) Pub. Date: May 30, 2024

(54) SEMICONDUCTOR PACKAGE AND METHOD OF MANUFACTURING THE SEMICONDUCTOR PACKAGE

(71) Applicant: SAMSUNG ELECTRONICS CO., LTD., SUWON-SI (KR)

(72) Inventor: DONGHYEON JANG, SUWON-SI (KR)

(21) Appl. No.: 18/235,033

(22) Filed: Aug. 17, 2023

(30) Foreign Application Priority Data
Nov. 25, 2022 (KR) 10-2022-0160419

(51) Int. Cl. H01L 23/00; H01L 21/48; H01L 21/56; H01L 23/498; H01L 25/10; H01L 25/18; H10B 80/00

(52) U.S. Cl. CPC H01L 24/20; H01L 21/4857; H01L 21/568; H01L 23/49822; H01L 23/49838; H01L 24/16; H01L 24/19; H01L 25/105; H01L 25/18; H10B 80/00; H01L 23/3128

(57) ABSTRACT

A semiconductor package includes a lower redistribution wiring layer having first redistribution wirings stacked in at least two layers, a semiconductor chip disposed on the lower redistribution wiring layer and electrically connected to the first redistribution wirings, a sealing member covering the semiconductor chip on the lower redistribution wiring layer, a plurality of through vias penetrating the sealing member and electrically connected to the first redistribution wirings, and an upper redistribution wiring layer disposed on the sealing member and having second redistribution wirings electrically connected to the plurality of through vias. Each of the first redistribution wirings includes a barrier layer pattern, a seed layer pattern and a plating pattern sequentially stacked. From a plan view, a sidewall of the barrier layer pattern extends laterally beyond a sidewall of the seed layer pattern.

### CROSS-REFERENCE TO RELATED APPLICATIONS

A claim of priority under 35 U.S.C. § 119 is made to Korean Patent Application No. 10-2022-0160419, filed on Nov. 25, 2022 in the Korean Intellectual Property Office (KIPO), the entirety of which is hereby incorporated by reference.

### BACKGROUND

The present disclosure relate to semiconductor packages and methods of manufacturing semiconductor packages. More particularly, the present disclosure relates to fan out packages and methods of manufacturing fan out packages.

A lower redistribution wiring layer of a fan out package may include redistribution wirings stacked in at least two layers. The redistribution wirings may include a redistribution line extending in one direction and having a fine line width. In order to form a redistribution line, a plating wiring line of the redistribution line may be formed on a seed layer and a barrier layer. The seed layer and the barrier layer under the plating wiring line may be partially removed by a wet etching process. However, there are problems with this approach in that an undercut is generated in the seed layer and the barrier layer by the wet etching process, and an etchant penetrates an interface of the barrier layer, thereby resulting in the redistribution line peeling off.

### SUMMARY

Embodiments of the inventive concepts provide a semiconductor package including fine redistribution wirings having structural stability, and a method of manufacturing the semiconductor package.

Embodiments of the inventive concepts provide a semiconductor package including a lower redistribution wiring layer having first redistribution wirings stacked in at least two layers; a semiconductor chip on the lower redistribution wiring layer and electrically connected to the first redistribution wirings; a sealing member covering the semiconductor chip on the lower redistribution wiring layer; a plurality of through vias penetrating the sealing member and electrically connected to the first redistribution wirings; and an upper redistribution wiring layer on the sealing member and having second redistribution wirings electrically connected to the plurality of through vias. Each of the first redistribution wirings includes a barrier layer pattern, a seed layer pattern and a plating pattern sequentially stacked. From a plan view, a sidewall of the barrier layer pattern extends laterally beyond a sidewall of the seed layer pattern.

Embodiments of the inventive concepts further provide a semiconductor package including a lower redistribution wiring layer having first redistribution wirings stacked in at least two layers; a semiconductor chip disposed on the lower redistribution wiring layer, the semiconductor chip having a first surface with chip pads on the first surface, and the first surface facing the lower redistribution wiring layer; a sealing member covering the semiconductor chip on the lower redistribution wiring layer; a plurality of through vias penetrating the sealing member and electrically connected to the first redistribution wirings; and an upper redistribution wiring layer on the sealing member. Each of the first redistribution wirings includes a barrier layer pattern, a seed layer pattern and a plating pattern sequentially stacked on one another. From a plan view, a sidewall of the barrier layer pattern extends laterally beyond a sidewall of the seed layer pattern.

Embodiments of the inventive concepts still further provide a semiconductor package including a lower redistribution wiring layer having first redistribution wirings stacked in at least two layers; a semiconductor chip on the lower redistribution wiring layer and electrically connected to the first redistribution wirings; a sealing member covering the semiconductor chip on the lower redistribution wiring layer; a plurality of through vias penetrating the sealing member and electrically connected to the first redistribution wirings; and an upper redistribution wiring layer on the sealing member. Each of the first redistribution wirings includes a redistribution via penetrating an underlying insulating layer, a redistribution pad on the redistribution via, and a redistribution line extending from the redistribution pad on the underlying insulating layer. The redistribution line includes a barrier layer pattern, a seed layer pattern and a plating pattern sequentially stacked on the underlying insulating layer. The redistribution line includes a recess configured by a sidewall of the seed layer pattern recessed from a sidewall of the plating pattern and a sidewall of the barrier layer pattern.

Embodiments also provide a method of manufacturing a semiconductor package, including forming a lower redistribution wiring layer having first redistribution wirings stacked in at least two layers. A semiconductor chip is disposed on the lower redistribution wiring layer, the semiconductor chip having chip pads that are electrically connected to the first redistribution wirings. A sealing member is formed on the lower redistribution wiring layer to cover the semiconductor chip. A plurality of through vias are formed to vertically penetrate the sealing member and to be electrically connected to the first redistribution wirings. An upper redistribution wiring layer is disposed on the sealing member, the upper redistribution wiring layer having second redistribution wirings that are electrically connected to the plurality of through vias. To form the lower redistribution wiring layer having the first redistribution wirings, a barrier layer and a seed layer are sequentially formed on an insulating layer, a photoresist pattern having an opening that exposes a redistribution region is formed on the seed layer, a plating pattern is formed in the opening, the photoresist layer is removed, a portion of the seed layer exposed by the plating pattern is removed by an isotropic etching process to form a seed layer pattern, and a portion of the barrier layer exposed by the plating pattern is removed by an anisotropic etching process.

According to example embodiments, a lower redistribution wiring layer may include first redistribution wirings stacked in at least two layers. The first redistribution wirings may include a first lower redistribution wiring, a second lower redistribution wiring and a third lower redistribution wiring stacked in three layers. Each of the first, second and third lower redistribution wirings may include a barrier layer pattern, a seed layer pattern and a plating pattern sequentially stacked on one another. Each of the first, second and third lower redistribution wirings may include a redistribution via, a redistribution line, and a redistribution pad.

Since the barrier layer pattern of the redistribution line is formed by an anisotropic etching process using the overlying plating pattern as an etching mask, the occurrence of an undercut in a sidewall of the barrier layer pattern may be prevented or reduced. Accordingly, the sidewall of the barrier layer pattern may be positioned outside a sidewall of the overlying seed layer pattern, or in other words the sidewall of the barrier layer pattern may extend beyond a sidewall of the overlying seed layer pattern, to thereby prevent the occurrence of a defect whereby the redistribution line having a fine line width is separated from an underlying insulating layer. Thus, structural stability of the fine lower redistribution wirings may be secured.

### BRIEF DESCRIPTION OF THE DRAWINGS

Example embodiments will be more clearly understood from the following detailed description taken in conjunction with the accompanying drawings.

FIG. 1 illustrates a cross-sectional view of a semiconductor package in accordance with embodiments of the inventive concepts.

FIG. 2 illustrates an enlarged cross-sectional view of portion ‘A’ in FIG. 1.

FIG. 3 illustrates a plan view of first lower redistribution wirings in FIG. 1.

FIG. 4 illustrates an enlarged cross-sectional view of portion ‘B’ in FIG. 2.

FIGS. 5, 6, 7, 8, 9, 10, 11, 12, 13, 14, 15, 16, 17, 18, 19, 20, 21, 22, 23, 24, 25, 26 and 27 illustrate views explanatory of a method of manufacturing a semiconductor package in accordance with embodiments of the inventive concepts.

FIG. 28 illustrates a cross-sectional view of a semiconductor package in accordance with embodiments of the inventive concepts.

FIG. 29 illustrates a cross-sectional view of a semiconductor package in accordance with embodiments of the inventive concepts.

FIG. 30 illustrates an enlarged cross-sectional view of portion ‘G’ in FIG. 29.

FIGS. 31, 32, 33, 34, 35, 36, 37, 38, 39, 40, 41, 42, 43, 44, 45, 46, 47, 48, 49, 50 and 51 illustrate cross-sectional views explanatory of a method of manufacturing a semiconductor package in accordance with embodiments of the inventive concepts.

### DETAILED DESCRIPTION

Hereinafter, example embodiments will be explained in detail with reference to the accompanying drawings. Herein, like reference numerals will denote like elements, and redundant descriptions thereof will be omitted for conciseness. Throughout the description, relative locations of components may be described using terms such as “vertical”, “horizontal”, “over”, “higher” and so on. These terms are for descriptive purposes only, and are intended only to describe the relative locations of components assuming the orientation of the overall device is the same as that shown in the drawings. The embodiments, however, are not limited to the illustrated device orientations.

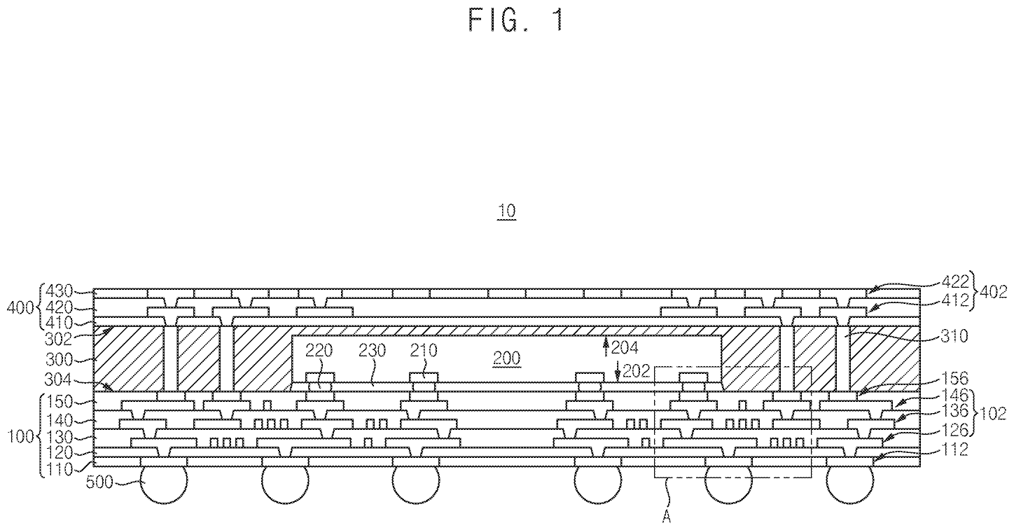

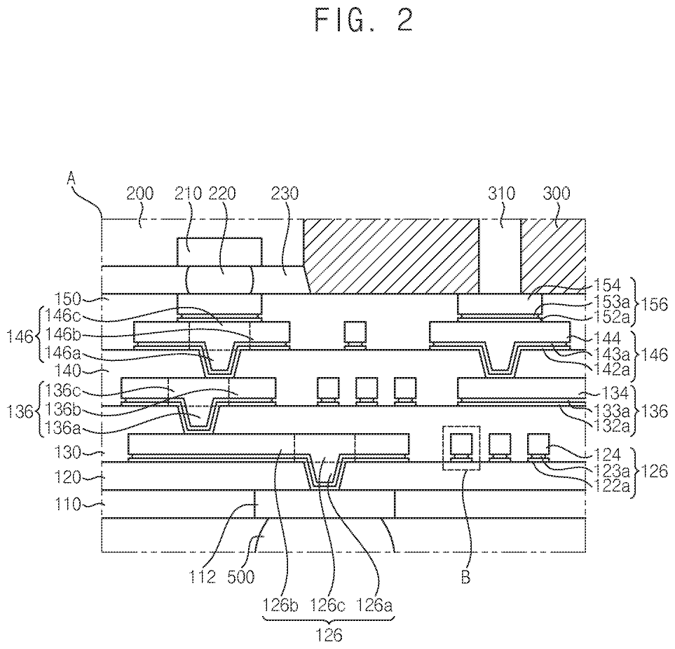

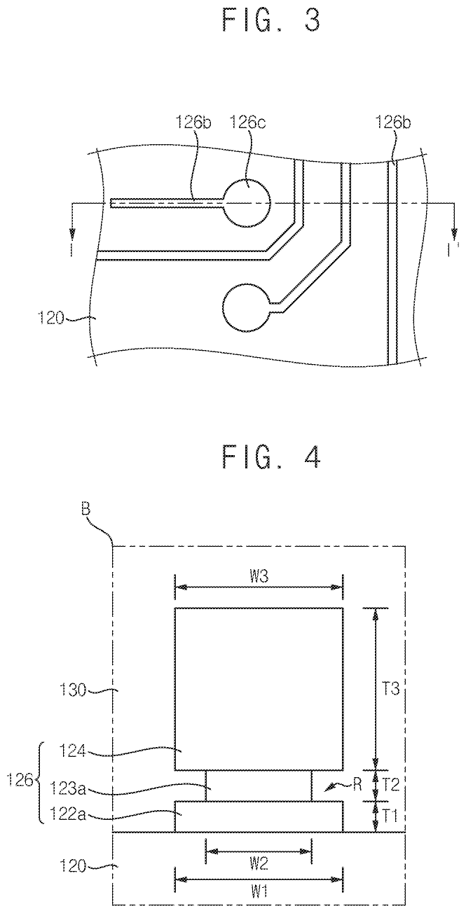

FIG. 1 illustrates a cross-sectional view of a semiconductor package in accordance with embodiments of the inventive concepts. FIG. 2 illustrates an enlarged cross-sectional view of portion ‘A’ in FIG. 1. FIG. 3 illustrates a plan view of first lower redistribution wirings in FIG. 1. FIG. 4 illustrates an enlarged cross-sectional view of portion ‘B’ in FIG. 2. FIG. 2 is a cross-sectional view taken along the line I-I′ in FIG. 3.

Referring to FIGS. 1 to 4, a semiconductor package 10 may include a lower redistribution wiring layer 100, a semiconductor chip 200 disposed on the lower redistribution wiring layer 100, and a sealing member 300 covering at least a portion of the semiconductor chip 200 on an upper surface of the lower redistribution wiring layer 100, and an upper redistribution wiring layer 400 disposed on an upper surface 302 of the sealing member 300. In addition, the semiconductor package 10 may further include external connection members 500 disposed on an outer surface of the lower redistribution wiring layer 100.

In example embodiments, the semiconductor package 10 may be a fan out package in which the lower redistribution wiring layer 100 extends to the sealing member 300 covering a side surface of the semiconductor chip 200. The lower redistribution wiring layer 100 may be formed by a wafer level redistribution wiring process. Additionally, the semiconductor package 10 may be provided as a unit package on which a second package is stacked.

Further, the semiconductor package 10 may be provided as a System In Package (SIP). For example, one or more semiconductor chips may be disposed on the lower redistribution wiring layer 100. The semiconductor chips may include a logic chip including a logic circuit and/or a memory chip. The logic chip may be a controller that controls memory chips. The memory chip may include various types of memory circuits, such as for example DRAM, SRAM, flash memory, PRAM, ReRAM, FeRAM, or MRAM.

In example embodiments, the lower redistribution wiring layer 100 may have first redistribution wirings 102. The semiconductor chip 200 may be disposed on the lower redistribution wiring layer 100 to be electrically connected to the first redistribution wirings 102. The lower redistribution wiring layer 100 may be provided on a front surface 202 of the semiconductor chip 200 to serve as a front redistribution wiring layer. Accordingly, the lower redistribution wiring layer 100 may be a front redistribution wiring layer (FRDL) of the fan out package.

In particular, the lower redistribution wiring layer 100 includes a plurality of first, second, third, fourth and fifth lower insulating layers 110, 120, 130, 140 and 150, and the first redistribution wirings 102 provided in the first, second, third, fourth and fifth lower insulating layers. The first redistribution wirings 102 may include first, second and third lower redistribution wirings 126, 136 and 146.

The first, second, third, fourth and fifth lower insulating layers may include a polymer or a dielectric layer. For example, the first, second, third, fourth and fifth lower insulating layers may include a photosensitive insulating layer such as photo imagable dielectric (PID). The first, second, third, fourth and fifth lower insulating layers may be formed by a vapor deposition process, a spin coating process, etc. The first redistribution wirings may include aluminum (Al), copper (Cu), tin (Sn), nickel (Ni), gold (Au), platinum (Pt), or an alloy thereof. The first redistribution wirings may be formed by a plating process, an electroless plating process, a vapor deposition process, etc.

In particular, a first bonding pad 112 may be provided in the first lower insulating layer 110. The first bonding pad 112 may be a bump pad. The bump pad may include a solder pad or a pillar pad. For example, the first bonding pad may include copper (Cu), aluminum (Al), tin (Sn), nickel (Ni), gold (Au), platinum (Pt), or an alloy thereof.

The second lower insulating layer 120 may be formed on the first lower insulating layer 110, and the first lower redistribution wiring 126 may be formed on the second lower insulating layer 120. The first lower redistribution wiring 126 may be electrically connected to the first bonding pad 112 through a first opening formed in the second lower insulating layer 120.

The third lower insulating layer 130 may be formed on the second lower insulating layer 120, and the second lower redistribution wiring 136 may be formed on the second lower insulating layer 130. The second lower redistribution wiring 136 may be electrically connected to the first lower redistribution wiring 126 through a second opening formed in the third lower insulating layer 130.

The fourth lower insulating layer 140 may be formed on the third lower insulating layer 130, and the third lower redistribution wiring 146 may be formed on the fourth lower insulating layer 140. The third lower redistribution wiring 146 may be electrically connected to the second lower redistribution wiring 136 through a third opening formed in the fourth lower insulating layer 140.

A second bonding pad 156 may be disposed on the third lower redistribution wiring 146. A solder resist layer 150 serving as a fifth lower insulating layer may be formed on the fourth lower insulating layer 140 and may expose at least a portion of the second bonding pad 156. The solder resist film 150 may serve as a passivation layer.

The numbers and arrangements of the lower insulating layers and the lower redistribution wirings of the lower redistribution wiring layer are provided as examples, and it should be appreciated that the inventive concepts are not limited thereto.

As illustrated in FIGS. 2 and 3, the first lower redistribution wiring 126 may include a first barrier layer pattern 122a, a first seed layer pattern 123a and a first plating pattern 124 sequentially stacked on the second lower insulating layer 120. The first lower redistribution wiring 126 may include a first redistribution via 126a, a first redistribution line 126b and a first redistribution pad 126c. The first redistribution via 126a may be formed to penetrate the second lower insulating layer 120. The first redistribution line 126b may extend on the second lower insulating layer 120.

For example, the first barrier layer pattern 122a may include titanium, titanium nitride, tantalum, tantalum nitride, tungsten, etc. The first seed layer pattern 123a may include copper, gold, silver, aluminum, or an alloy thereof. The first plating pattern 124 may include copper (Cu), aluminum (Al), tin (Sn), nickel (Ni), gold (Au), platinum (Pt), or an alloy thereof.

As illustrated in FIG. 4, when viewed from a plan view, a sidewall of the first barrier layer pattern 122a may be positioned outside a sidewall of the first seed layer pattern 123a. In other words for example, the first barrier layer pattern 122a may extend laterally beyond a sidewall of the first seed layer pattern 123a. The sidewall of the first seed layer pattern 123a may be positioned inside a sidewall of the first plating pattern 124. In other words for example, a sidewall of the first plating pattern 124 may extend laterally beyond a sidewall of the first seed layer pattern 123a. The sidewall of the first barrier layer pattern 122a may be positioned on substantially the same vertical plane as the sidewall of the first plating pattern 124. In other words for example, the sidewall of the first barrier layer pattern 122a and the sidewall of the first plating pattern 124 may be vertically aligned with each other. The sidewall of the first seed layer pattern 123a may form a recess R recessed from the sidewall of the first plating pattern 124 and the sidewall of the first barrier layer pattern 122a. This may be appreciated in view of FIG. 4, whereby the first barrier layer pattern 122a may have a width W1, the first seed layer pattern 123a may have a width W2, and the first plating pattern may have a width W3. The width W1 may be greater than the width W2, the width W3 may be greater than the width W2, and the width W3 and the width W1 may be substantially equal to each other to configure recess R.

The first barrier layer pattern 122a may have a thickness T1 of about 500 Å to about 2,000 Å. The first seed layer pattern 123a may have a thickness T2 of about 500 Å to about 1,500 Å. The first plating pattern 124 may have a thickness T3 of 2 μm to 10 μm. The first redistribution line 126b may have a width of 3 μm or less. For example, the first redistribution line 126b may have a width of 2 μm. A diameter of the first redistribution pad 126b may be within a range of 200 μm to 350 μm.

Since the first barrier layer pattern 122a of the first redistribution line 126b is formed by an anisotropic etching process using the first plating pattern 124 as an etching mask, an excessive undercut may be prevented or reduced from being generated in the sidewall of the first barrier layer pattern 122a. Accordingly, the sidewall of the first barrier layer pattern 122a may be positioned outside the sidewall of the first seed layer pattern 123a (i.e., may extend laterally beyond), thereby preventing a defect in which the first redistribution line 126b having a fine line width is peeled off second lower insulating layer 120 for example.

Similarly, the second lower redistribution wiring 136 may include a second barrier layer pattern 132a, a second seed layer pattern 133a and a second plating pattern 134 sequentially stacked on the third lower insulating layer 130. The second lower redistribution wiring 136 may include a second redistribution via 136a, a second redistribution line 136b and a second redistribution pad 136c. The second redistribution via 136a may be formed to penetrate the third lower insulating layer 130. The second redistribution line 136b may extend on the third lower insulating layer 130.

The third lower redistribution wiring 146 may include a third barrier layer pattern 142a, a third seed layer pattern 143a and a third plating pattern 144 sequentially stacked on the fourth lower insulating layer 140. The third lower redistribution wiring 146 may include a third redistribution via 146a, a third redistribution line 146b and a third redistribution pad 146c. The third redistribution via 146a may be formed to penetrate the fourth lower insulating layer 140. The third redistribution line 146b may extend on the fourth lower insulating layer 140.

The second bonding pad 156 may include a fourth barrier layer pattern 152a, a fourth seed layer pattern 153a and a fourth plating pattern 154 sequentially stacked on the third lower redistribution wiring 146. The second bonding pad 156 may further include additional plating patterns formed on the fourth plating pattern 154. The plating pattern may include nickel, gold, silver, etc.

In example embodiments, the semiconductor chip 200 may have a plurality of chip pads 210 on a first surface 202, that is, an active surface. The semiconductor chip 200 may be mounted on the lower redistribution wiring layer 100 such that the first surface on which the chip pads 210 are formed faces the lower redistribution wiring layer 100.

The semiconductor chip 200 may be mounted on the lower redistribution wiring layer 100 by a flip chip bonding method. The semiconductor chip 200 may be mounted on the lower redistribution wiring layer 100 via conductive bumps 220. The conductive bumps 220 may be disposed between the bonding pad 156 on the third lower redistribution wiring 146 of the lower redistribution wiring layer 100 and the chip pad 210 of the semiconductor chip 200 and electrically connect them. For example, the conductive bumps 220 may include a pillar bump formed on the chip pad 210 of the semiconductor chip 200 and a solder bump formed on the pillar bump. Alternatively, the conductive bump 220 may include only a solder bump formed on the chip pad 210 of the semiconductor chip 200. An underfill member 230 may be disposed between the semiconductor chip 200 and the lower redistribution wiring layer 100.

Although only a few chip pads are illustrated in the figures, the structure and arrangement of the chip pads are provided as examples, and it should be understood that the inventive concepts are not limited thereto. Additionally, although only one semiconductor chip is illustrated, embodiments are not limited thereto, and a plurality of semiconductor chips may be stacked on the lower redistribution wiring layer 100.

In example embodiments, the sealing member 300 may cover at least a portion of the semiconductor chip 200 on the upper surface of the lower redistribution wiring layer 100. The sealing member 300 may include a first molding portion covering an upper surface 204 of the semiconductor chip 200 and a second sealing portion covering the upper surface of the lower redistribution wiring layer 100 around the semiconductor chip 200.

For example, the sealing member 300 may include an epoxy mold compound (EMC). The sealing member 300 may be formed by a molding process, a screen printing process, a lamination process, etc.

In example embodiments, a plurality of through vias 310 may extend in a vertical direction to penetrate the sealing member 300. The through via 310 may be formed on the second bonding pad 156 on the third lower redistribution wiring 146.

The through via 310 may be provided to penetrate the sealing member 300 and may serve as an electrical connector. The through via 310 may be a through mold via (TMV) formed to penetrate the second sealing portion of the sealing member 300. That is, the through vias 310 may be provided in the fan out region outside the area where the semiconductor chip 200 is disposed to electrically connect the lower redistribution wiring layer 100 and the upper redistribution wiring layer 400.

In example embodiments, the upper redistribution wiring layer 400 may disposed on the sealing member 300 and include second redistribution wirings 402 electrically connected to the through vias 310 respectively. The second redistribution wirings 402 may include upper redistribution wirings of at least two layers stacked on the upper surface 302 of the sealing member 300. The second redistribution wirings 402 may be provided on the sealing member 300 to serve as backside redistribution wirings. Accordingly, the upper redistribution wiring layer 400 may be a backside redistribution wiring layer (BRDL) of the fan out package.

The second redistribution wirings 402 may include a first upper redistribution wiring 412 and a second upper redistribution wiring 422 stacked in two layers. In this case, the second upper redistribution wiring 422 may correspond to the uppermost redistribution wiring among the second redistribution wirings 402.

A first upper insulating layer 410 may be provided on the upper surface 302 of the sealing member 300 and may have openings that expose upper surfaces of the through vias 310. The first upper redistribution wirings 412 may be formed on the first upper insulating layer 410 and at least portions of the first upper redistribution wirings 412 may directly contact the through vias 310 through the openings.

A second upper insulating layer 420 may be provided on the first upper insulating layer 410 and may have openings that expose the first upper redistribution wirings 412. The second upper redistribution wirings 422 may be formed on the second upper insulating layer 420 and at least portions of the second upper redistribution wirings 422 may directly contact the first upper redistribution wirings 412 through the openings.

Although not illustrated in the drawings, upper bonding pads may be respectively provided on the second upper redistribution wirings 422. A third upper insulating layer 430 may be provided on the second upper insulating layer 420 and may expose at least portions of the second upper redistribution wirings 422 and upper bonding pads (not shown). The third upper insulating layer 430 may serve as a passivation layer.

For example, the first, second and third upper insulating layers 410, 420 and 430 may include a polymer or a dielectric layer. The first, second and third upper insulating layers 410, 420 and 430 may include a photosensitive insulating material (PID) or an insulating film such as ABF. The second redistribution wirings 402 may include copper (Cu), aluminum (Al), tin (Sn), nickel (Ni), gold (Au), platinum (Pt), or an alloy thereof.

The number and arrangement of the upper insulating layers 410, 420 and 430, and the upper redistribution wirings 412 and 422 of the upper redistribution wiring layer 400 are provided as examples, and it should be understood that the inventive concepts are not limited thereto.

In example embodiments, the external connection members 500 may be disposed on the first bonding pads 112 on the outer surface of the lower redistribution wiring layer 100. For example, the external connection member 500 may include a solder ball. The solder ball may have a diameter of 300 μm to 500 μm. The semiconductor package 10 may be mounted on a module substrate (not illustrated) via the solder balls to form a memory module.

As mentioned above, the semiconductor package 10 as a fan out wafer level package may include the lower redistribution wiring layer 100, the semiconductor chip 200 disposed on the lower redistribution wiring layer 100, the sealing member 300 covering at least a portion of the semiconductor chip 200 on the upper surface of the lower redistribution wiring layer 100, the plurality of through vias 310 penetrating the sealing member 300, and the upper redistribution wiring layer 400 disposed on the upper surface 302 of the sealing member 300.

The lower redistribution wiring layer 100 may include the first redistribution wirings 102 stacked in at least two layers. The first redistribution wirings 102 may include the first lower redistribution wiring 126, the second lower redistribution wiring 136 and the third lower redistribution wiring 146 stacked in three layers. Each of the first, second and third lower redistribution wirings 126, 136 and 146 may respectively include the barrier layer patterns 122a, 132a and 142a, the seed layer patterns 123a, 133a and 143a and the plating patterns 124, 134 and 144 sequentially stacked on one another. Each of the first, second and third lower redistribution wirings 126, 136 and 146 may respectively include the redistribution vias 126a, 136a and 146a, the redistribution lines 126b, 136b and 146b, and the redistribution pads 126c, 136c and 146c.

Since the barrier layer pattern of the redistribution line is formed by an anisotropic etching process using the overlying plating pattern as an etching mask, an undercut may be prevented or reduced from being formed in the sidewall of the barrier layer pattern. Accordingly, the sidewall of the barrier layer pattern may be positioned outside the sidewall of the overlying seed layer pattern (i.e., may extend laterally beyond), to thereby prevent a defect whereby the redistribution line having a fine line width is separated from the underlying insulating layer. Thus, structural stability of the fine redistribution wirings may be secured.

Hereinafter, a method of manufacturing the semiconductor package of FIG. 1 will be described.

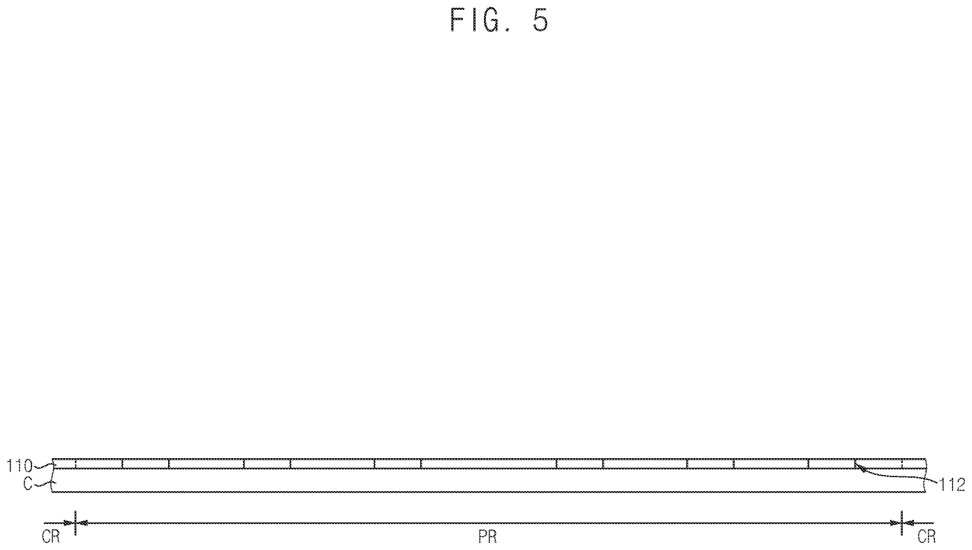

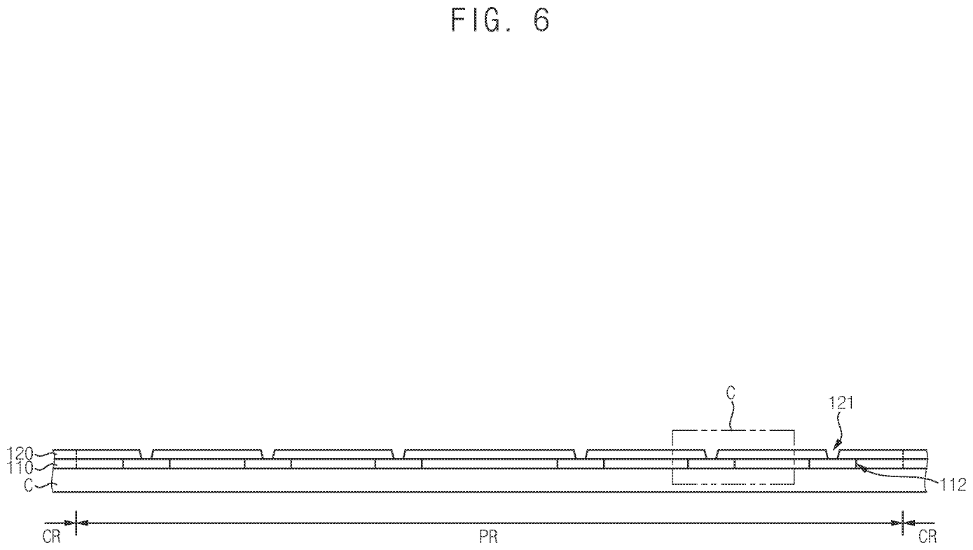

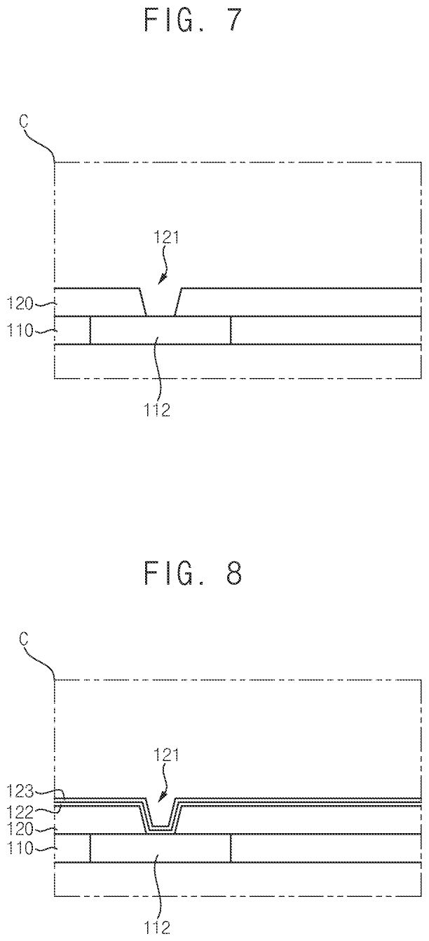

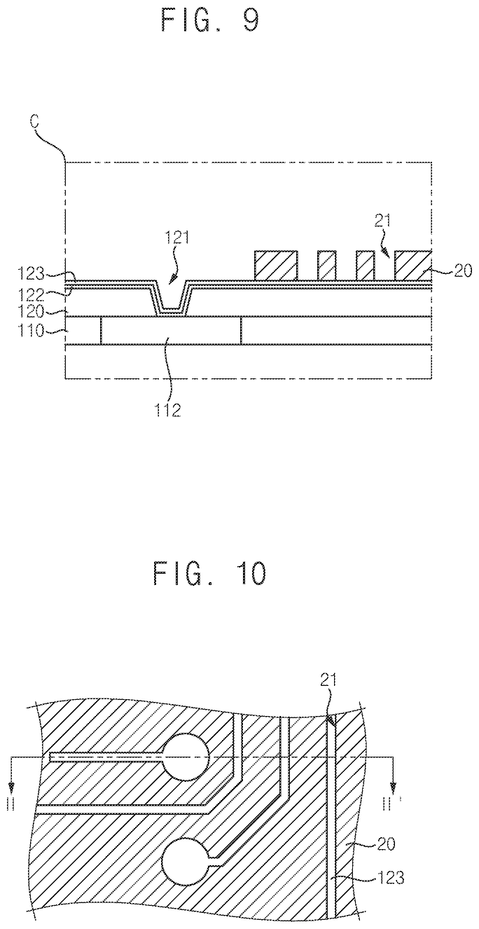

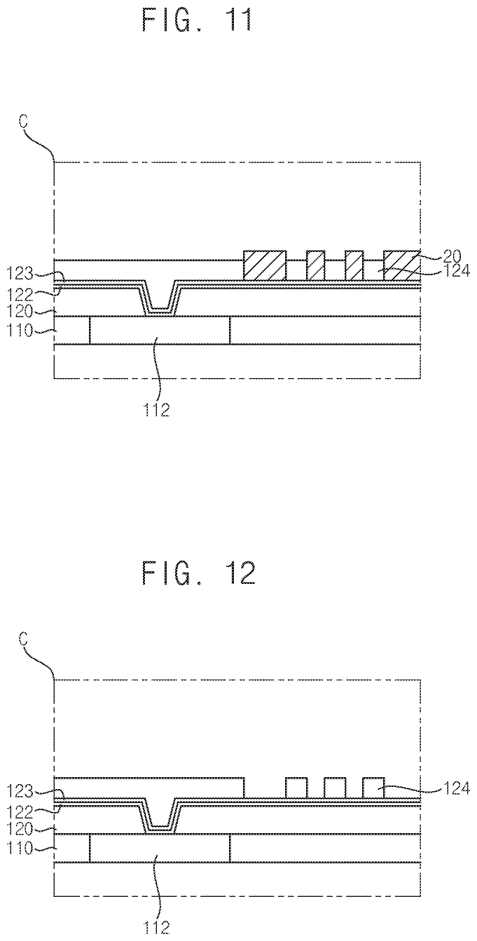

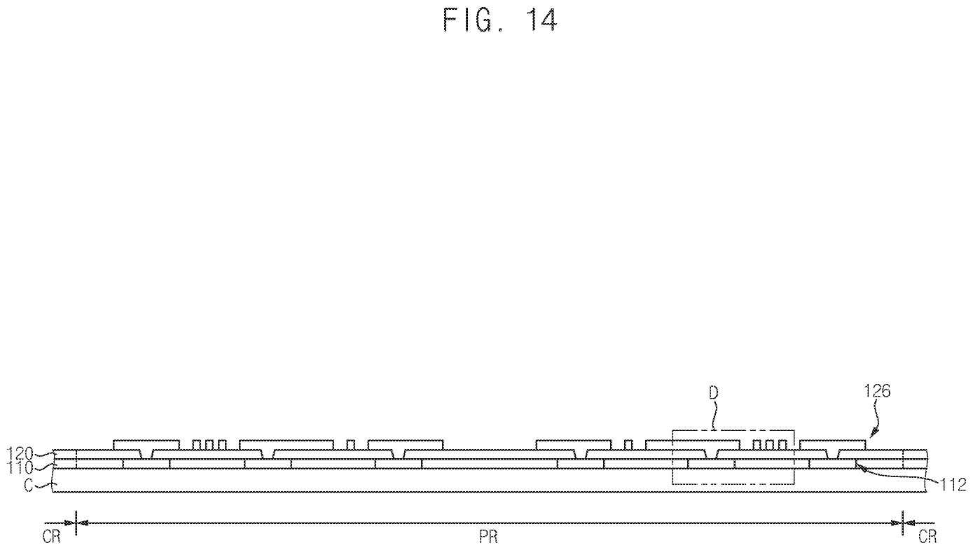

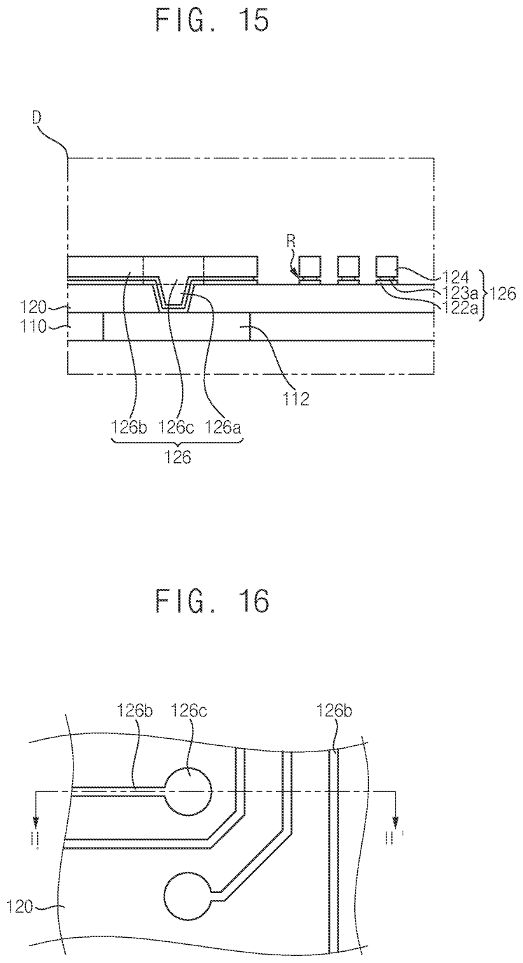

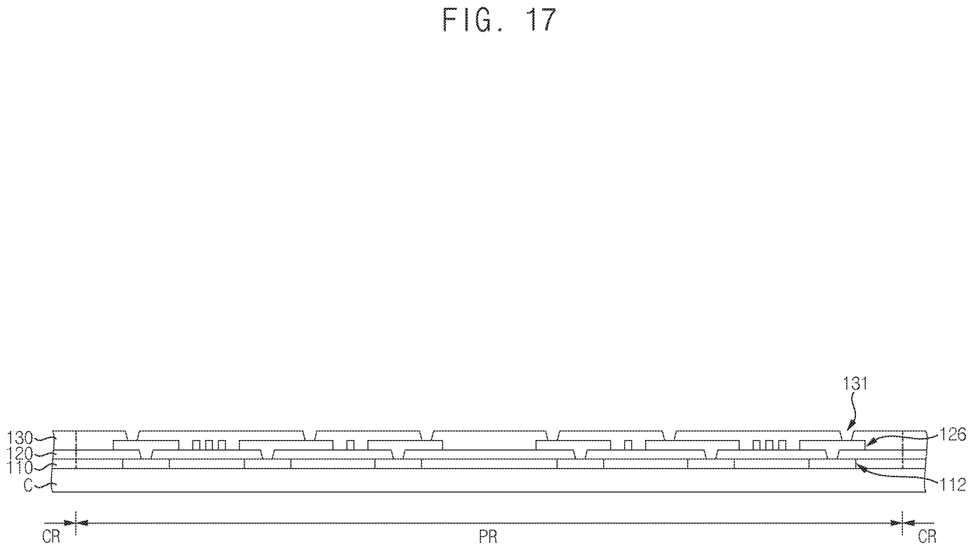

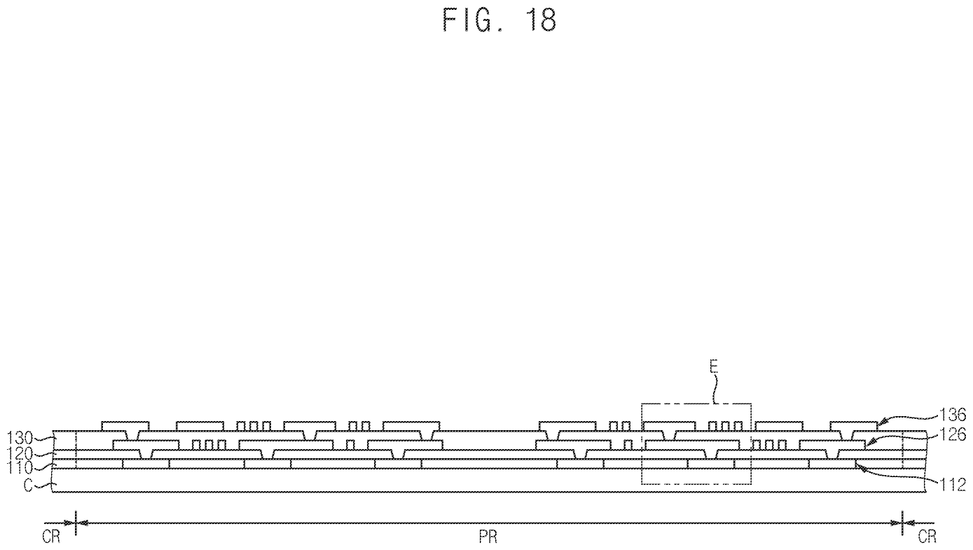

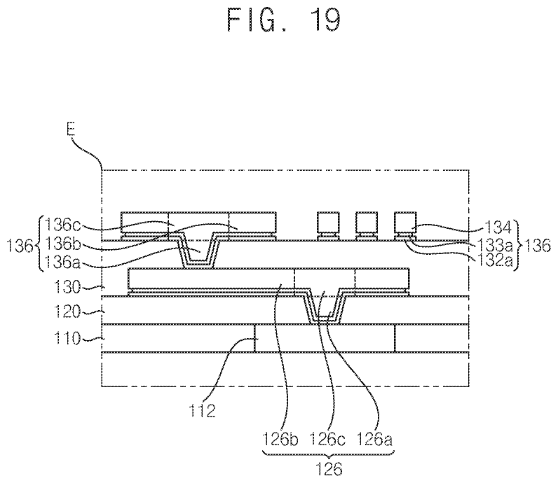

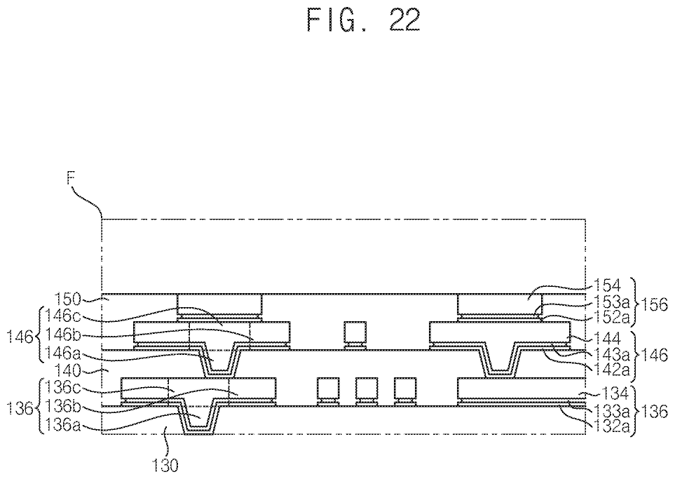

FIGS. 5 to 27 illustrate views explanatory of a method of manufacturing a semiconductor package in accordance with embodiments of the inventive concepts. FIGS. 5 to 9, 11 to 15, and 17 to 27 illustrate cross-sectional views explanatory of the method of manufacturing a semiconductor package in accordance with example embodiments. FIGS. 7 to 9 and 11 to 13 illustrate enlarged cross-sectional views of portion ‘C’ in FIG. 6. FIG. 10 illustrates a plan view of FIG. 9. FIG. 15 illustrates an enlarged cross-sectional view of portion ‘D’ in FIG. 14. FIG. 16 illustrates a plan view of FIG. 15. FIG. 19 illustrates an enlarged cross-sectional view of portion ‘E’ in FIG. 18. FIG. 22 illustrates an enlarged cross-sectional view of portion ‘F’ in FIG. 21. FIG. 9 illustrates a cross-sectional view taken along the line II-II′ in FIG. 10. FIG. 15 illustrates a cross-sectional view taken along the line II-II′ in FIG. 16.

Referring to FIGS. 5 to 22, a lower redistribution wiring layer 100 having first redistribution wirings 102 may be formed on a carrier substrate C.

In example embodiments, the carrier substrate C may include a wafer substrate as a base substrate on which a plurality of semiconductor chips are disposed on the lower redistribution wiring layer and a sealing member is formed to cover them. The carrier substrate C may have a shape corresponding to a wafer on which a semiconductor process is performed. For example, the carrier substrate C may include a silicon substrate, a glass substrate, a non-metal or metal plate, etc.

The carrier substrate C may include a package region PR on which the semiconductor chip is mounted and a cutting region CR surrounding the package region PR. As will be described later, the lower redistribution wiring layer 100 and the sealing member 300 formed on the carrier substrate C may be cut along the cutting region CR that divides the plurality of package regions MR to be individualized.

As illustrated in FIG. 5, a plating process may be performed on the carrier substrate C to form a first lower insulating layer 110 including first bonding pads 112 formed therein. Although not illustrated in the figures, after sequentially forming a release film, a barrier metal layer, a seed layer and the first lower insulating layer on a carrier substrate C, the first lower insulating layer may be patterned to form an opening that exposes a first bonding pad region. Then, the plating process may be performed on the seed layer to form the first bonding pads 112 in the openings.

For example, the first lower insulating layer 110 may include a polymer or a dielectric layer. The first lower insulating layer 110 may include a photosensitive insulating material (PID) or an insulating film such as ABF. The first lower insulating layer may be formed by a spin coating process, a vapor deposition process, etc.

When the first lower insulating layer includes a photosensitive insulating material such as PID, after a barrier metal layer, a seed layer and the photosensitive insulating layer are formed on the carrier substrate C, the photosensitive insulating layer may be patterned to form a preliminary opening that exposes the first bonding pad region. The photosensitive insulating layer may be patterned by performing an exposure process and a development process. Then, a curing process of the photosensitive insulating layer may be performed such that a portion of the photosensitive insulating layer flows down toward the preliminary opening to form a tapered opening. Then, a plating process may be performed to form the first bonding pad in the tapered opening of the photosensitive insulating layer.

In this case, the first bonding pad may have a shape corresponding to the tapered opening. A diameter of a lower surface of the first bonding pad may be greater than a diameter of an upper surface of the first bonding pad, and a sidewall of the first bonding pad may be inclined to have an acute angle of 45 degrees to 80 degrees with respect to a lower surface of the photosensitive insulating layer.

The first bonding pad 112 may be a bump pad. The bump pad may include a solder pad or a pillar pad. For example, the first bonding pad may include copper (Cu), aluminum (Al), tin (Sn), nickel (Ni), gold (Au), platinum (Pt), or an alloy thereof.

As illustrated in FIGS. 6 and 7, after a second lower insulating layer 120 is formed on the first lower insulating layer 110 to cover the first bonding pads 112, the second lower insulating layer 120 may be patterned to form first openings 121 that expose at least portions of the first bonding pads 112.

For example, the second lower insulating layer 120 may include a polymer or a dielectric layer. The second lower insulating layer 110 may include a photosensitive insulating material (PID) or an insulating film such as ABF. The second lower insulating layer may be formed by a spin coating process, a vapor deposition process, etc.

When the second lower insulating layer includes a photosensitive insulating material, the second lower insulating layer may be patterned by an exposure process and a developing process to form a preliminary opening. Then, a curing process of the second lower insulating layer may be performed such that a portion of the second lower insulating layer flows down toward the preliminary opening to form a tapered first opening 121. In this case, a diameter of a lower surface of the first opening may be greater than a diameter of an upper surface of the first opening, and a sidewall of the first opening may be inclined to have an acute angle of 45 degrees to 80 degrees with respect to a lower surface of the second lower insulating layer.

As illustrated in FIG. 8, a barrier layer 122 and a seed layer 123 may be sequentially formed on the second lower insulating layer 120. The barrier layer 122 may be formed on a sidewall of the first opening 121 of the second lower insulating layer 120 and a portion of the first bonding pad 112 exposed by the first opening 121.

For example, the barrier layer 122 may include titanium, titanium nitride, tantalum, tantalum nitride, tungsten, etc. The seed layer 123 may include copper, gold, silver, aluminum, or an alloy thereof. The barrier layer and the seed layer may be formed by a physical vapor deposition method or the like. The barrier layer 122 may have a thickness of about 500 Å to about 2,000 Å. The seed layer 123 may have a thickness of about 500 Å to about 1,500 Å.

As illustrated in FIGS. 9 and 10, a photoresist layer may be formed on the seed layer 123 and an exposure process and a development process may be performed on the photoresist layer to form a photoresist pattern 20 having an opening 21 that exposes a first lower redistribution region.

As illustrated in FIGS. 11 and 12, a first plating pattern 124 may be formed in the opening 21 of the photoresist pattern 20, and the photoresist pattern 20 may be removed from the second lower insulating layer 120. The first plating pattern 124 may be formed by an electroplating process or an electroless plating process. For example, the first plating pattern 124 may have a thickness of 2 μm to 10 μm.

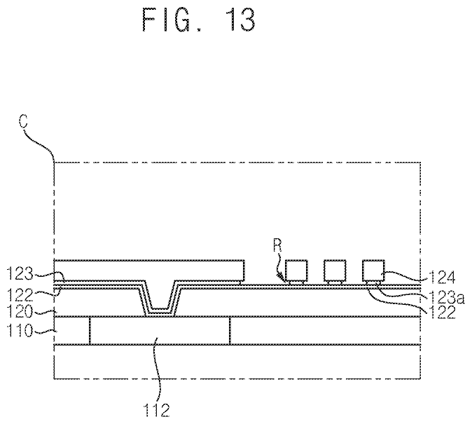

As illustrated in FIG. 13, a portion of the seed layer 123 exposed by the first plating pattern 124 may be removed to form a first seed layer pattern 123a. The portion of the seed layer 123 exposed by the first plating pattern 124 may be removed by an isotropic etching process. The portion of the seed layer 123 may be removed by a wet etching process.

When the seed layer 123 includes copper, an etchant may include copper ammonium chloride (Cu(NH₃)C₁₂), ammonia (NH₃), ammonium chloride (NH₄Cl), dilute phosphoric acid (H₃PO₄), hydrogen peroxide, etc. Since the portion of the seed layer 123 is removed by an isotropic etching process, a portion of the seed layer 123 below a peripheral portion of the first plating pattern 124 may be removed. Accordingly, when viewed from a plan view, a sidewall of the first seed layer pattern 123a may be positioned inside a sidewall of the first plating pattern 124. The sidewall of the first seed layer pattern 123a may form a recess R recessed from the sidewall of the first plating pattern 124.

As illustrated in FIGS. 14 to 16, a portion of the barrier layer 122 exposed by the first seed layer pattern 123a may be removed to form a first barrier layer pattern 122a. A portion of the barrier layer 122 exposed by the first plating pattern 124 may be removed by an anisotropic etching process. The portion of the barrier layer 122 may be removed by a dry etching process.

When the barrier layer 122 includes titanium, an etching gas may include a fluorine-based gas such as CF₄ or CHF₄, or a chlorine-based gas such as Cl₂. Since the portion of the barrier layer 122 is removed by an anisotropic etching process, the portion of the barrier layer 122 exposed from an outer surface of the first plating pattern 124 may be removed. Accordingly, a sidewall of the first barrier layer pattern 122a may be positioned on substantially the same vertical plane as a sidewall of the first plating pattern 124. When viewed from a plan view, the sidewall of the first barrier layer pattern 122a may be positioned outside the sidewall of the first seed layer pattern 123a. In other words, the sidewall of the first barrier layer pattern 122a may extend laterally beyond the first seed layer pattern 123a. The sidewall of the first seed layer pattern 123a may form a recess R recessed from the sidewall of the first plating pattern 124 and the sidewall of the first barrier layer pattern 122a.

Thus, a first lower redistribution wiring 126 including the first barrier layer pattern 122a, the first seed layer pattern 123a and the first plating pattern 124 may be formed on the second lower insulating layer 120. The first lower redistribution wiring 126 may be electrically connected to the first bonding pad 112 through the first opening 121 of the second lower insulating layer 120.

The first lower redistribution wiring 126 may include a first redistribution via 126a, a first redistribution line 126b and a first redistribution pad 126c. The first redistribution via 126a may be formed to penetrate the second lower insulating layer 120. The first redistribution line 126b may extend on the second lower insulating layer 120. The first redistribution line 126b may have a width of 3 μm or less. For example, the first redistribution line 126b may have a width of 2 μm. A diameter of the first redistribution pad 126b may be within a range of 200 μm to 350 μm.

If the first barrier layer pattern 122a was formed by an isotropic etching process (in contrast to an anisotropic etching process as described with respect to FIG. 15), a recess recessed from the sidewall of the first seed layer pattern 123a would be formed in a sidewall of the first barrier layer pattern 122a and an etchant for removing titanium would permeate the interface of the first barrier layer pattern 122a so that the first redistribution line 126b may be separated from the second lower insulating layer 120. However, since the first barrier layer pattern 122a of the first redistribution line 126b is formed by an anisotropic etching process, a side portion of the first barrier layer pattern 122a is not undercut and the sidewall of the first barrier layer pattern 122a may be positioned outside the sidewall of the first seed layer pattern 123a. In other words, the sidewall of the first barrier layer pattern 122a extends laterally beyond the first seed layer pattern 123a. Accordingly, a defect in which the fine first redistribution line 126b is separated from the second lower insulating layer 120 may be prevented.

As illustrated in FIG. 17, processes the same as or similar to the processes described with reference to FIGS. 6 and 7 may be performed to form a third lower insulating layer 130 on the second lower insulating layer 120 to cover the first lower redistribution wirings 126 and to pattern the third lower insulating layer 130 to form second openings 131 that expose at least portions of the first lower redistribution wirings 126.

As illustrated in FIGS. 18 and 19, processes the same as or similar to the processes described with reference to FIGS. 8 to 16 may be performed to form second lower redistribution wirings 136 on the third lower insulating layer 130.

For example, a barrier layer and a seed layer may be sequentially formed on the third lower insulating layer 130, and a photoresist pattern having an opening that exposes a second lower redistribution region may be formed on the seed layer. Then, a second plating pattern 134 may be formed in the opening of the photoresist pattern by a plating process, and the photoresist pattern may be removed from the second lower insulating layer 130.

Then, a portion of the seed layer exposed by the second plating pattern 134 may be removed to form a second seed layer pattern 133a. The portion of the seed layer exposed by the second plating pattern 134 may be removed by an isotropic etching process. The portion of the seed layer may be removed by a wet etching process.

Then, a portion of the barrier layer exposed by the second seed layer pattern 133a may be removed to form a second barrier layer pattern 132a. The portion of the barrier layer exposed by the second seed layer pattern 133a may be removed by an anisotropic etching process. The portion of the barrier layer may be removed by a dry etching process.

Thus, the second lower redistribution wiring 136 including the second barrier layer pattern 132a, the second seed layer pattern 133a and the second plating pattern 134 may be formed on the third lower insulating layer 130. The second lower redistribution wiring 136 may be electrically connected to the first lower redistribution wiring 126 through the second opening 131 (see FIG. 17) of the third lower insulating layer 130.

The second lower redistribution wiring 136 may include a second redistribution via 136a, a second redistribution line 136b and a second redistribution pad 136c. The second redistribution via 136a may be formed to penetrate the third lower insulating layer 130. The second redistribution line 136b may extend on the third lower insulating layer 130. The second redistribution line 136b may have a width of 3 μm or less. For example, the second redistribution line 136b may have a width of 2 μm. The second barrier layer pattern 132a, the second seed layer pattern 133a and the second plating pattern 134 of the second lower redistribution wiring 136 may have widths and thicknesses the same as or similar to those of the first barrier layer pattern 122a, the first seed pattern 123a and the first plating pattern 124 of the first lower redistribution wiring 126.

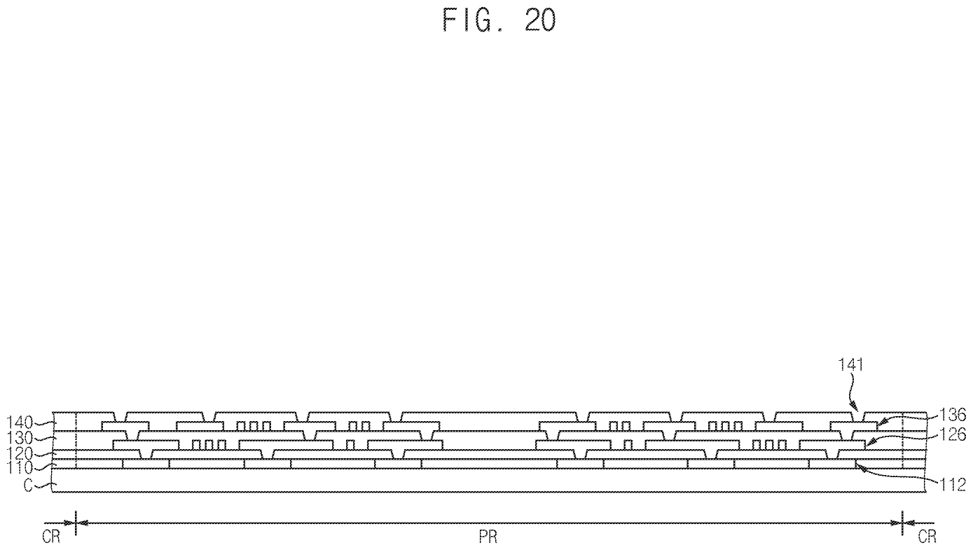

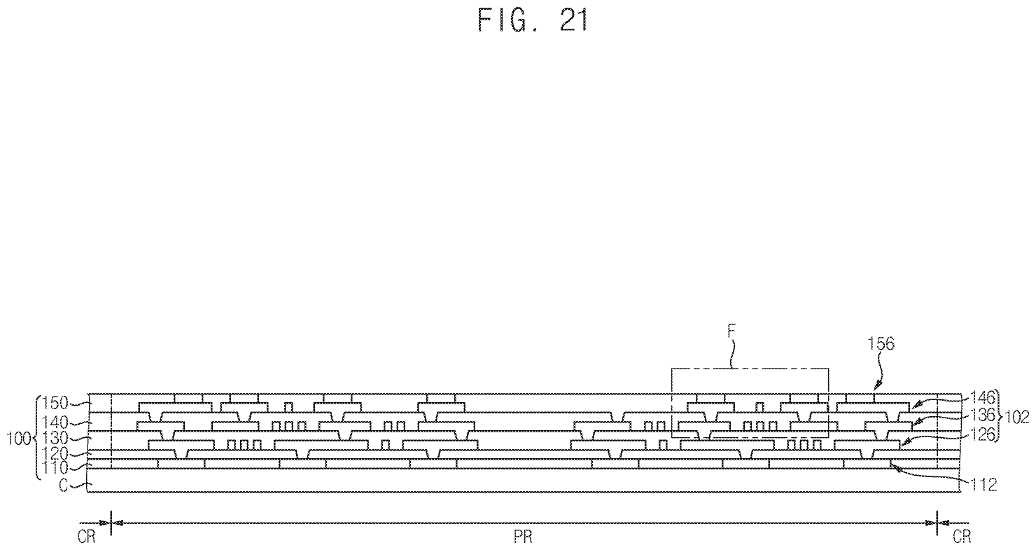

As illustrated in FIG. 20, processes the same as or similar to the processes described with reference to FIGS. 6 and 7 may be performed to a fourth lower insulating layer 140 on the third lower insulating layer 130 to cover the second lower redistribution wirings 136 and to pattern the fourth lower insulating layer 140 to form third openings 141 that expose at least portions of the second lower redistribution wirings 136.

As illustrated in FIGS. 21 and 22, processes the same as or similar to the processes described with reference to FIGS. 8 to 16 may be performed to form third lower redistribution wirings 146 on the fourth lower insulating layer 140. Then, second bonding pads 156 may be formed on the third lower redistribution wirings 146.

For example, a barrier layer and a seed layer may be sequentially formed on the fourth lower insulating layer 140, and a photoresist pattern having an opening that exposes a third lower redistribution region may be formed on the seed layer. Then, a third plating pattern 144 may be formed in the opening of the photoresist pattern by a plating process, and the photoresist pattern may be removed from the third lower insulating layer 140.

Then, a portion of the seed layer exposed by the third plating pattern 144 may be removed to form a third seed layer pattern 143a. The portion of the seed layer exposed by the third plating pattern 144 may be removed by an isotropic etching process. The portion of the seed layer may be removed by a wet etching process.

Then, a portion of the barrier layer exposed by the third seed layer pattern 143a may be removed to form a third barrier layer pattern 142a. The portion of the barrier layer exposed by the third seed layer pattern 143a may be removed by an anisotropic etching process. The portion of the barrier layer may be removed by a dry etching process.

Thus, the third lower redistribution wiring 146 including the third barrier layer pattern 142a, the third seed layer pattern 143a and the third plating pattern 144 may be formed on the fourth lower insulating layer 140. The third lower redistribution wiring 146 may be electrically connected to the second lower redistribution wiring 136 through the third opening 141 (see FIG. 20) of the fourth lower insulating layer 140.

The third lower redistribution wiring 146 may include a third redistribution via 146a, a third redistribution line 146b and a third redistribution pad 146c. The third redistribution via 146a may be formed to penetrate the fourth lower insulating layer 140. The third redistribution line 146b may extend on the fourth lower insulating layer 140. The third redistribution line 146b may have a width of 3 μm or less. For example, the third redistribution line 146b may have a width of 2 μm. The third barrier layer pattern 142a, the third seed layer pattern 143a and the third plating pattern 144 of the third lower redistribution wiring 146 may have widths and thicknesses the same as or similar to those of the first barrier layer pattern 122a, the first seed layer pattern 123a and the first plating pattern 124 of the first lower redistribution wiring 126.

Then, processes the same as or similar to the processes described with reference to FIGS. 8 to 16 may be performed to form the second bonding pads 156 on the third lower redistribution wirings 146.

The second bonding pad 156 including a fourth barrier layer pattern 152a, a fourth seed layer pattern 153a and a fourth plating pattern 154 may be formed on the third lower redistribution 146.

Then, a solder resist layer 150 as a fifth lower insulating layer may be formed on the fourth lower insulating layer 140 to cover the third redistribution wirings 146 and expose at least a portion of the second bonding pad 156.

Thus, the lower redistribution wiring layer 100 having the first to fifth lower insulating layers 110, 120, 130, 140 and 150 may be formed. The lower redistribution wiring layer 100 may be a front redistribution wiring layer (FRDL) of a fan-out package. The second bonding pads 156 may be exposed from an upper surface of the lower redistribution wiring layer 100.

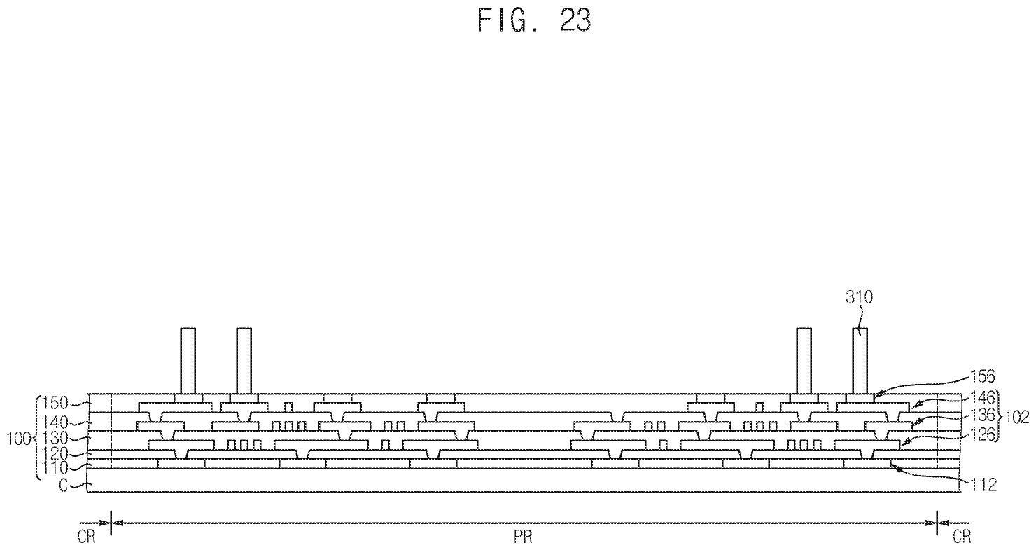

Referring to FIG. 23, a plurality of through vias 310 as conductive structures may be formed on the upper surface of the lower redistribution wiring layer 100.

In example embodiments, a photoresist layer may be formed on the upper surface of the lower redistribution wiring layer 100, and an exposure process may be performed on the photoresist layer to form a photoresist pattern having openings that are provided on a fan-out region of the lower redistribution wiring layer 100 for forming the plurality of through vias. The opening may expose at least a portion of the second bonding pad 156 in the fan-out region.

Then, an electro plating process may be performed to fill the openings of the photoresist pattern with a conductive material to form the through vias 310. Then, the photoresist pattern may be removed by a strip process.

The through vias 310 as conductive connection structures may extend upward from the second bonding pad 156. The through vias 310 may be electrically connected to the first redistribution wirings 102. As will be described later, the through via 310 may be provided to penetrate the sealing member and to serve as an electrical connector. That is, the through vias 310 may be provided in the fan-out region outside of an area where a semiconductor chip (die) is disposed and may be used for electrical connection.

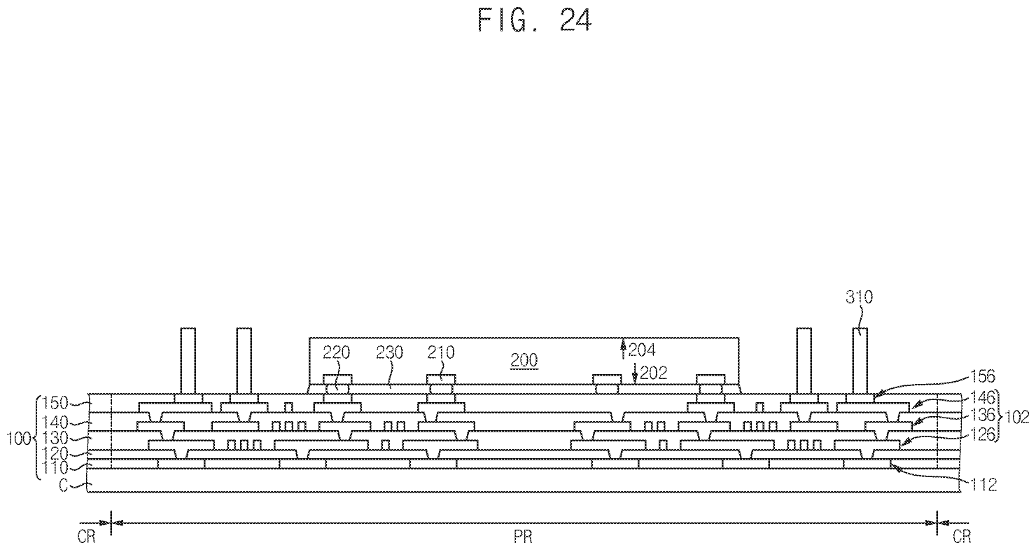

Referring to FIG. 24, at least one semiconductor chip 200 may be mounted on the upper surface of the lower redistribution wiring layer 100.

In example embodiments, the semiconductor chip 200 may be disposed in a fan in region of the lower redistribution wiring layer 100. The semiconductor chip 200 may be mounted on the upper surface of the lower redistribution wiring layer 100 by a flip chip bonding method. The semiconductor chip 200 may be disposed such that a front surface 202 on which chip pads 210 are formed, that is, an active surface faces the lower redistribution wiring layer 100. The chip pads 210 of the semiconductor chip 200 may be electrically connected to the second bonding pads 156 of the lower redistribution wiring layer 100 by conductive bumps 220. Accordingly, the semiconductor chip 200 may be electrically connected to the first redistribution wirings 102 of the lower redistribution wiring layer 100 by the conductive bumps 220. For example, the conductive bumps 220 may include micro bumps (uBumps).

An underfill member 230 may be underfilled between the semiconductor chip 200 and the lower redistribution wiring layer 100. The underfill member may include a material having relatively high fluidity to effectively fill a small space between the semiconductor chip and the lower redistribution wiring layer. For example, the underfill member may include an adhesive containing an epoxy material.

For example, the semiconductor chip may be a logic chip including a logic circuit. The logic chip may be a controller that controls memory chips. The semiconductor chip may be a processor chip such as an ASIC or an application processor (AP) serving as a host such as for example a CPU, GPU, or SOC.

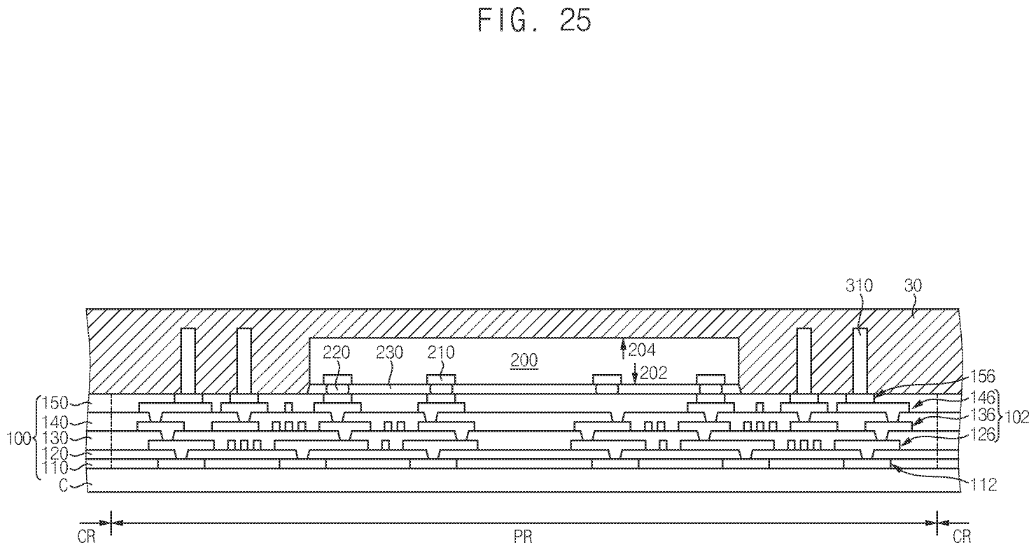

Referring to FIG. 25, a sealing material 30 may be formed on the upper surface of the lower redistribution wiring layer 100 to cover the semiconductor chip 200 and the plurality of through vias 310.

The sealing material 30 may be formed to cover an upper surface 204 of the semiconductor chip 200 and upper surfaces of the plurality of through vias 310. For example, the sealing material 30 may include an epoxy molding compound (EMC). The sealing material 30 may include UV resin, polyurethane resin, silicone resin, silica filler, etc.

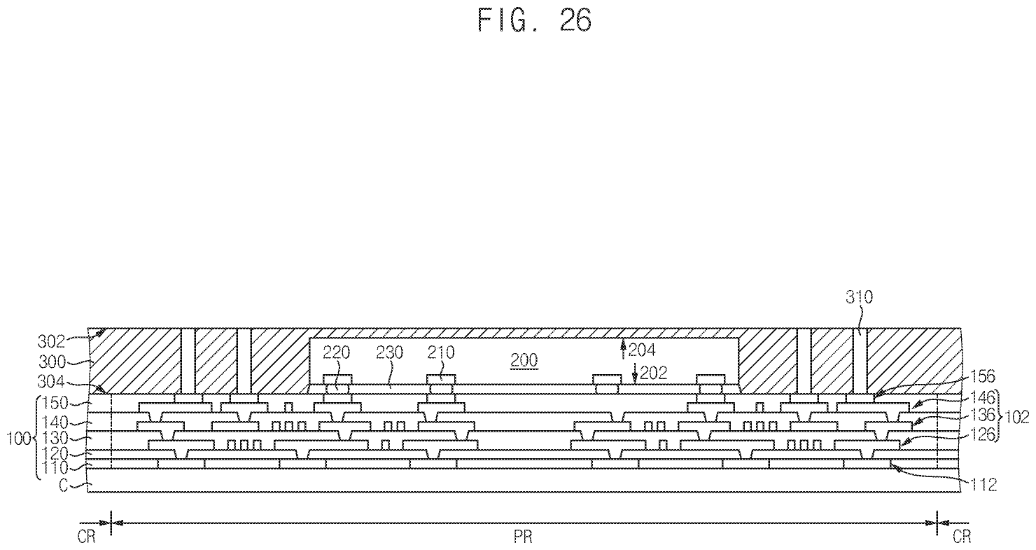

Referring to FIG. 26, an upper portion of the sealing material 30 may be partially removed to form a sealing member 300 that exposes the upper surfaces of the plurality of through vias 310. The upper portion of the sealing material 30 may be partially removed by a grinding process.

The sealing member 300 may include a first sealing portion covering the upper surface 204 of the semiconductor chip 200 and a second sealing portion covering the upper surface of the lower redistribution wiring layer 100 around the semiconductor chip 200.

Accordingly, the plurality of through vias 310 may be formed on the upper surface of the fan out region of the lower redistribution wiring layer 100 and may extend to penetrate the sealing member 300. The through via 310 may be a through mold via (TMV) formed to penetrate the second sealing portion of the sealing member 300.

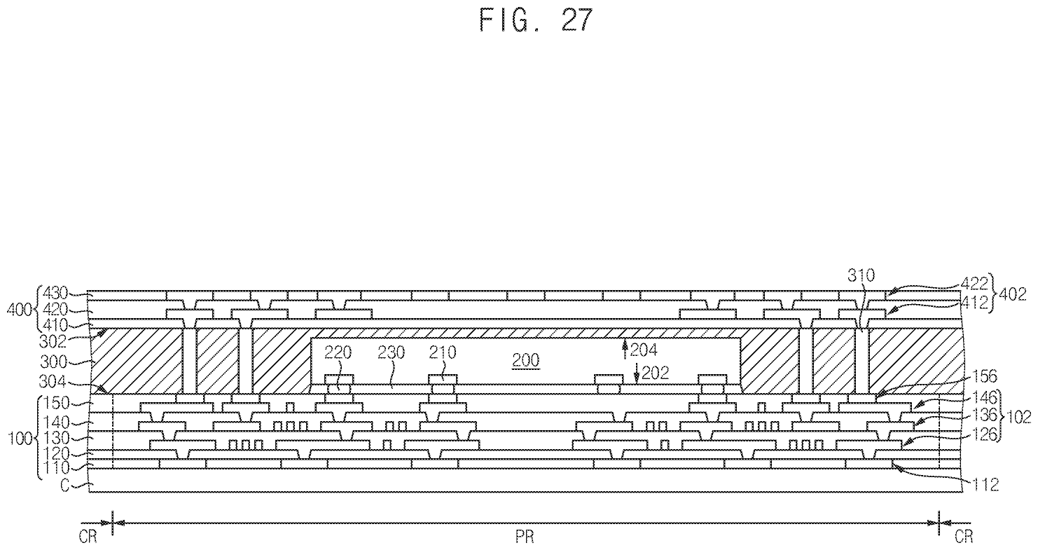

Referring to FIG. 27, an upper redistribution wiring layer 400 having second redistribution wirings 402 electrically connected to the through vias 310 may be formed on an upper surface 302 of the sealing member 300.

In example embodiments, after a first upper insulating layer 410 is formed on the upper surface 302 of the sealing member 300, the first upper insulating layer 410 may be patterned to form openings that expose the through vias 310 respectively. The openings of the patterned first upper insulating layer 410 may expose upper surfaces of the through vias 310.

Then, after a seed layer is formed on portions of the exposed through vias 310 and in the openings, the seed layer may be patterned and an electroplating process may be performed to form first upper redistribution wirings 412. Accordingly, at least some of the first upper redistribution wirings 412 may be electrically connected to the through vias 310 through the openings.

Then, after a second upper insulating layer 420 is formed on the first upper insulating layer 410, the second upper insulating layer 420 may be patterned to form openings that expose the first upper redistribution wirings 412. Then, second upper redistribution wirings 422 may be formed on the second upper insulating layer 420 to directly contact the first upper redistribution wirings 412 through the openings.

Thus, the second redistribution wirings 402 may include the first upper redistribution wiring 412 and the second upper redistribution wiring 422 stacked in two layers. In this case, the second upper redistribution wiring 422 may correspond to the uppermost redistribution wiring among the second redistribution wirings.

Then, upper bonding pads (not illustrated) may be formed on the second upper redistribution wirings 422 as the uppermost redistribution wirings, respectively, and a third upper insulating layer 430 may be formed on the second upper insulating layer 420 to expose at least portions of the second upper redistribution wirings 422 and the upper bonding pads (not shown). The third upper insulating layer 430 may serve as a passivation layer.

Then, external connection members 500 (see FIG. 1) may be formed on an outer surface, (i.e., a lower surface) of the lower redistribution wiring layer 100 to be electrically connected to the first redistribution wirings 102.

Then, a sawing process may be perform to individualize the lower redistribution wiring layer 100, to complete a fan out wafer level package 10 of FIG. 1 including the sealing member 300, the lower redistribution wiring layer 100 formed on a lower surface 304 of the sealing member 300 and the upper redistribution wiring layer 400 formed on the upper surface 302.

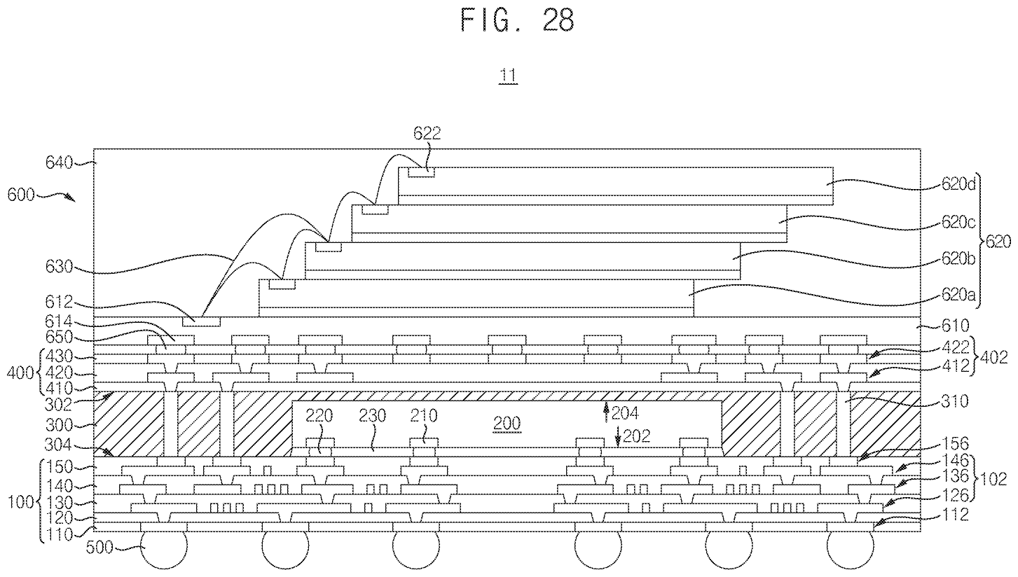

FIG. 28 illustrates a cross-sectional view of a semiconductor package in accordance with embodiments of the inventive concepts. The semiconductor package may be substantially the same as the semiconductor package described with reference to FIG. 1 except for an additional second package. Thus, same reference numerals may be used to refer to the same or like elements and any further repetitive explanation concerning the above elements may be omitted from the following description.

Referring to FIG. 28, a semiconductor package 11 may include a first package (e.g., similar to semiconductor package 10 shown in FIG. 1) and a second package 600 stacked on the first package. The semiconductor package 11 may further include a heat sink (not shown) stacked on the second package 600. The first package may include a lower redistribution wiring layer 100, a semiconductor chip 200, a sealing member 300 and an upper redistribution wiring layer 400. The first package may be substantially the same as or similar to the unit package described with reference to FIG. 1.

In example embodiments, the second package 600 may include a second package substrate 610, a plurality of second semiconductor chips 620 mounted on the second package substrate 610 and a sealing member 640 covering the second semiconductor chips 620 on the second package substrate 610.

The second package 600 may be stacked on the first package via conductive connection members 650. For example, the conductive connection members 650 may include solder balls, conductive bumps, etc. The conductive connection members 650 may be disposed between a bonding pad on a second upper redistribution wiring 422 of the upper redistribution wiring layer 400 and a second connection pad 614 of the second package substrate 610. Accordingly, the first package and the second package 600 may be electrically connected to each other by the conductive connection members 650.

The plurality of second semiconductor chips 620a, 620b, 620c and 620d may be sequentially stacked on the second package substrate 610 by adhesive members. Bonding wires 630 may connect second chip pads 622 of the second semiconductor chips 620 to first connection pads 612 of the second package substrate 610. The second semiconductor chips 620 may be electrically connected to the second package substrate 610 through the bonding wires 630.

Although the second package 600 includes four semiconductor chips mounted by a wire bonding method, it should be understood that the number of the semiconductor chips in the second package and the mounting method are not limited thereto.

Although not illustrated in the figure, the heat sink may be provided on the second package 600 to dissipate heat from the first and second packages to the outside. The heat sink may be attached on the second package 600 by using a thermal interface material (TIM).

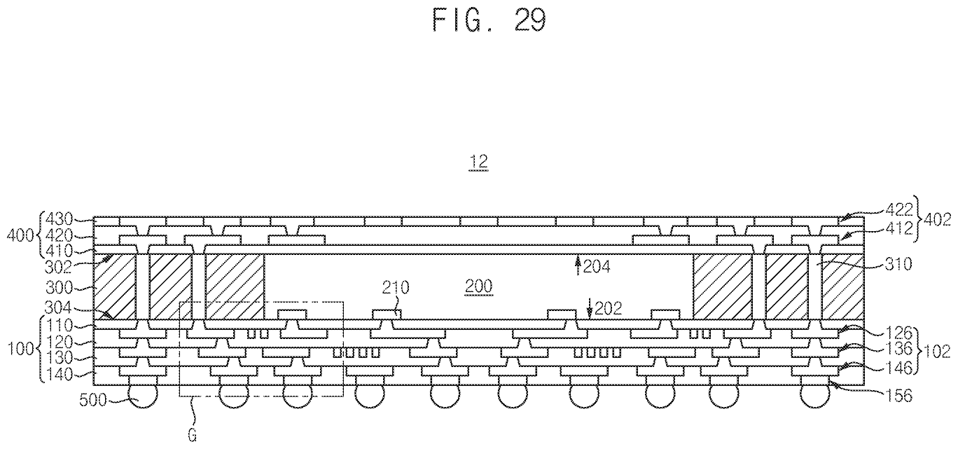

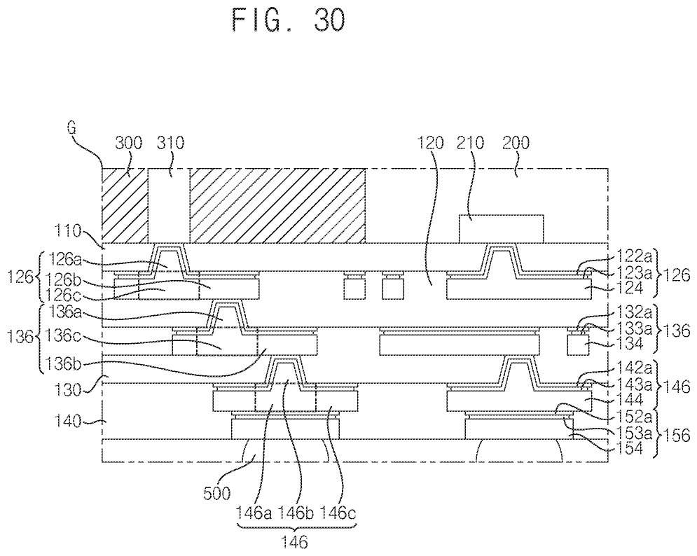

FIG. 29 illustrates a cross-sectional view of a semiconductor package in accordance with embodiments of the inventive concepts. FIG. 30 illustrates an enlarged cross-sectional view of portion ‘G’ in FIG. 29. The semiconductor package may be substantially the same as the semiconductor package described with reference to FIG. 1 except for an arrangement of a semiconductor chip and a configuration of a sealing member. Thus, same reference numerals may be used to refer to the same or like elements and any further repetitive explanation concerning the above elements may be omitted from the following description.

Referring to FIGS. 29 and 30, a semiconductor package 12 may include a lower redistribution wiring layer 100, a semiconductor chip 200 disposed on the lower redistribution wiring layer 100, a sealing member 300 covering at least a side of a semiconductor chip 200 on the lower redistribution wiring layer 100, and an upper redistribution wiring layer 400 disposed on the sealing member 300. In addition, the semiconductor package 12 may further include external connection members 500 disposed on an outer surface of the lower redistribution wiring layer 300.

In example embodiments, the semiconductor chip 200 may have a plurality of chip pads 210 on a first surface 202, that is, an active surface. The semiconductor chip 200 may be provided in the sealing member 300 such that the first surface 202 on which the chip pads 210 are formed faces the lower redistribution wiring layer 100. The sealing member 300 may cover an outer side surface of the semiconductor chip 200. The first surface 202 of the semiconductor chip 200 may be exposed from a second surface 304 of the sealing member 300, and a second surface 204 opposite to the first surface 202 of the semiconductor chip 200 may be exposed from a first surface 302 of the sealing member 300.

A plurality of through vias 310 may extend in a vertical direction to penetrate the sealing member 300. One end portion of the through via 310 may be exposed from the second surface 304 of the sealing member 300 and the other end portion of the through via 310 may be exposed from the first surface 302 of the sealing member 300.

In example embodiments, the lower redistribution wiring layer 100 may be disposed on the second surface 304 of the sealing member 300 and the first surface 202 of the semiconductor chip 200. The lower redistribution wiring layer 100 may include a plurality of first redistribution wirings 102. The first redistribution wirings 102 may be electrically connected to the chip pads 210 and the through vias 310 of the semiconductor chip 200, respectively. The first redistribution wirings 102 may be provided on the front surface 202 of the semiconductor chip 200 and the second surface 304 of the sealing member 300 to serve as front redistribution wirings. Accordingly, the lower redistribution wiring layer 100 may be a front redistribution wiring layer of the fan out package.

For example, the lower redistribution wiring layer 100 may include first, second, third and fourth lower insulating layers 110, 120, 130 and 140 sequentially stacked on the second surface 304 of the sealing member 300. The first redistribution wirings 102 may include first, second and third lower redistribution wirings 126, 136 and 146 stacked in at least three layers.

The first lower insulating layer 110 may be formed on the second surface 304 of the sealing member 300 and the front surface 202 of the semiconductor chip 200, and the first lower redistribution wirings 126 may be formed on the first lower insulating layer 110. The first lower redistribution wirings 126 may be electrically connected to the through vias 310 and the chip pads 210 through first openings formed in the first lower insulating layer 110.

The second lower insulating layer 120 may be formed on the first lower insulating layer 110, and the second lower redistribution wirings 136 may be formed on the second lower insulating layer 120. The second lower redistribution wirings 136 may be electrically connected to the first lower redistribution wirings 126 through second openings formed in the second lower insulating layer 120.

The third lower insulating layer 130 may be formed on the second lower insulating layer 120, and the third lower redistribution wirings 146 may be formed on the third lower insulating layer 130. The third lower redistribution wirings 146 may be electrically connected to the second lower redistribution wirings 136 through third openings formed in the third lower insulating layer 130.

A second bonding pad 156 may be disposed on the third lower redistribution wiring 146. A solder resist layer 140 serving as the fourth lower insulating layer may be formed on the third lower insulating layer 130 and may expose at least a portion of the second bonding pad 156. The solder resist layer 140 may serve as a passivation layer.

The number and arrangement of the lower insulating layers and the lower redistribution wirings of the lower redistribution wiring layer 100 are provided as examples, and it should be appreciated that the inventive concepts are not limited thereto.

As illustrated in FIG. 30, the first lower redistribution wiring 126 may include a first barrier layer pattern 122a, a first seed layer pattern 123a and a first plating pattern 124 sequentially stacked on the first lower insulating layer 110. The first lower redistribution wiring 126 may include a first redistribution via 126a, a first redistribution line 126b and a first redistribution pad 126c. The first redistribution via 126a may be formed to penetrate the first lower insulating layer 110. The first redistribution line 126b may extend on the first lower insulating layer 110.

When viewed from a plan view, a sidewall of the first barrier layer pattern 122a may be positioned outside a sidewall of the first seed layer pattern 123a. In other words, a sidewall of the first barrier layer pattern 122a extends laterally beyond a sidewall of the first seed layer pattern 123a. The sidewall of the first seed layer pattern 123a may be positioned inward of a sidewall of the first plating pattern 124. The sidewall of the first barrier layer pattern 122a may be positioned on substantially the same vertical plane as the sidewall of the first plating pattern 124. The sidewall of the first seed layer pattern 123a may form a recess recessed from the sidewall of the first plating pattern 124 and the sidewall of the first barrier layer pattern 122a.

Since the first barrier layer pattern 122a of the first redistribution line 126b is formed by an anisotropic etching process using the first plating pattern 124 as an etching mask, an excessive undercut may be prevented or reduced from being formed in the sidewall of the first barrier layer pattern 122a. Accordingly, the sidewall of the first barrier layer pattern 122a may be positioned outside the sidewall of the first seed layer pattern 123a, to thereby prevent a defect in which the first redistribution line 126b having a fine line width is peeled off the first lower insulating layer 110.

Similarly, the second lower redistribution wiring 136 may include a second barrier layer pattern 132a, a second seed layer pattern 133a and a second plating pattern 134 sequentially stacked on the second lower insulating layer 120. The second lower redistribution wiring 136 may include a second redistribution via 136a, a second redistribution line 136b and a second redistribution pad 136c. The second redistribution via 136a may be formed to penetrate the second lower insulating layer 120. The second redistribution line 136b may extend on the second lower insulating layer 120.

The third lower redistribution wiring 146 may include a third barrier layer pattern 142a, a third seed layer pattern 143a and a third plating pattern 144 sequentially stacked on the third lower insulating layer 130. The third lower redistribution wiring 146 may include a third redistribution via 146a, a third redistribution line 146b and a third redistribution pad 146c. The third redistribution via 146a may be formed to penetrate the third lower insulating layer 130. The third redistribution line 146b may extend on the third lower insulating layer 130.

The second bonding pad 156 may include a fourth barrier layer pattern 152a, a fourth seed layer pattern 153a and a fourth plating pattern 154 sequentially stacked on the third lower redistribution wiring 146. The second bonding pad 156 may further include additional plating patterns formed on the fourth plating pattern 154. The plating pattern may include nickel, gold, silver, etc.

Returning to FIG. 29, in example embodiments, the upper redistribution wiring layer 400 may be disposed on the first surface 302 of the sealing member 300 and the second surface 204 of the semiconductor chip 200, and may include second redistribution wirings 402 electrically connected to the through vias 310 and may also include the first upper insulating layer 410, the second upper insulating layer 420 and the third upper insulating layer 430. The second redistribution wirings 402 may include upper redistribution wirings 412 and 422 stacked in at least two layers. The second redistribution wirings 402 may be provided on the sealing member 300 to serve as backside redistribution wirings. Accordingly, the upper redistribution wiring layer 400 may be a backside redistribution wiring layer of the fan out package.

In example embodiments, the external connection members 500 may be disposed on the second bonding pads 156 on the third lower redistribution wirings 146 on the outer surface of the lower redistribution wiring layer 100. For example, the external connection member 500 may include a solder ball. The semiconductor package 12 may be mounted on a module substrate (not illustrated) via the solder balls to form a memory module.

Hereinafter, a method of manufacturing the semiconductor package of FIG. 29 will be described.

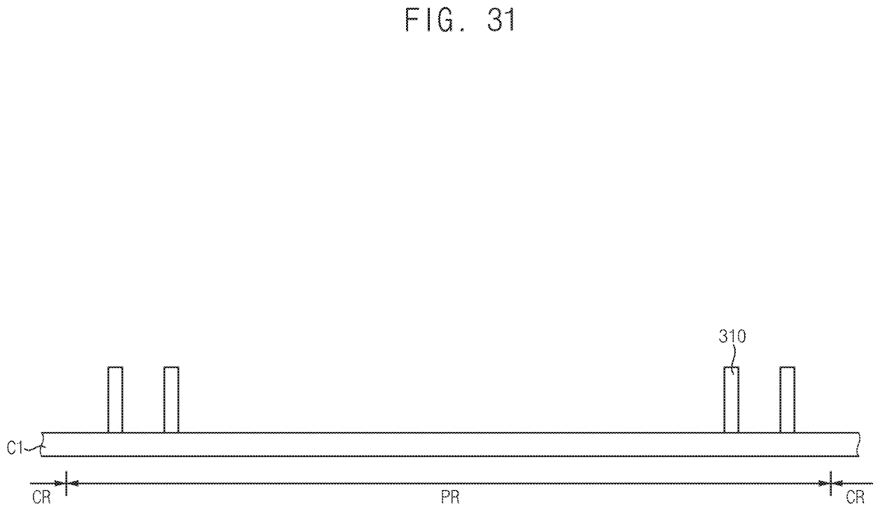

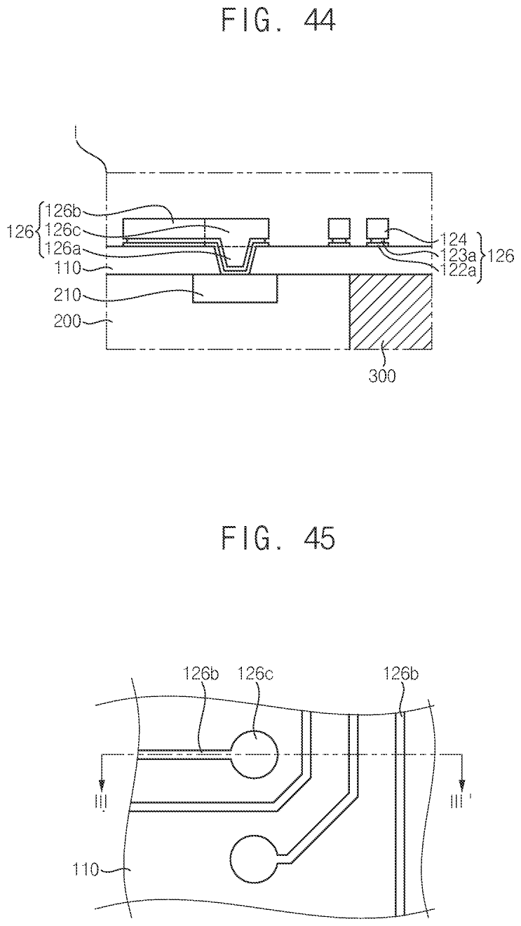

FIGS. 31 to 51 illustrate cross-sectional views explanatory of a method of manufacturing a semiconductor package in accordance with embodiments of the inventive concepts.

Referring to FIG. 31, a plurality of through vias 310 as conductive structures may be formed on a first carrier substrate C1.

In example embodiments, the first carrier substrate C1 may be used as a base substrate for stacking a plurality of semiconductor chips and forming a molding member covering them. The first carrier substrate C1 may have a shape corresponding to a wafer on which a semiconductor process is performed. The first carrier substrate C1 may include a package region PR on which the semiconductor chip is mounted and a cutting region CA surrounding the package region PR. As will be described later, a lower redistribution wiring layer and the molding member formed on the first carrier substrate C1 may be cut along the cutting region CA that divides the plurality of package regions PR to be individualized.

In particular, a seed layer and a photoresist layer may be formed on the first carrier substrate C1, and an exposure process may be performed on the photoresist layer to form a photoresist pattern having openings that are provided on a fan out region for forming the plurality of through vias 310.

Then, an electroplating process may be performed to fill the openings of the photoresist pattern with a conductive material to form the through vias 310. Then, the photoresist pattern may be removed by a strip process and a portion of the seed layer exposed by the through vias 310 may be removed.

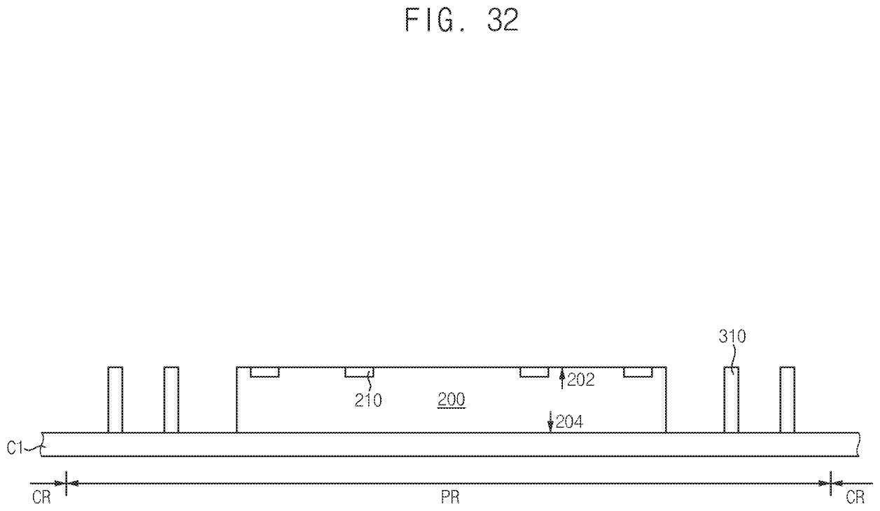

Referring to FIG. 32, at least one semiconductor chip 200 may be disposed on the first carrier substrate C1.

In example embodiments, the semiconductor chip 200 may be disposed in a fan in region of the first carrier substrate C1. The plurality of through vias 310 may be disposed around the semiconductor chip 200. The semiconductor chip 200 may be disposed such that a backside surface 204 opposite to a front surface 202 on which chip pads 210 are formed faces the first carrier substrate C1. That is, in example embodiments, the semiconductor chip 200 may have a plurality of chip pads 210 on a first surface 202, that is, an active surface.

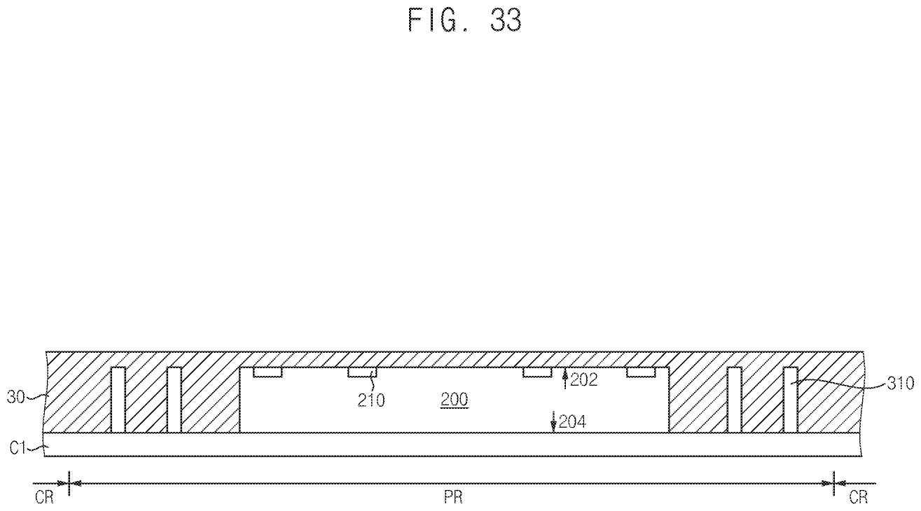

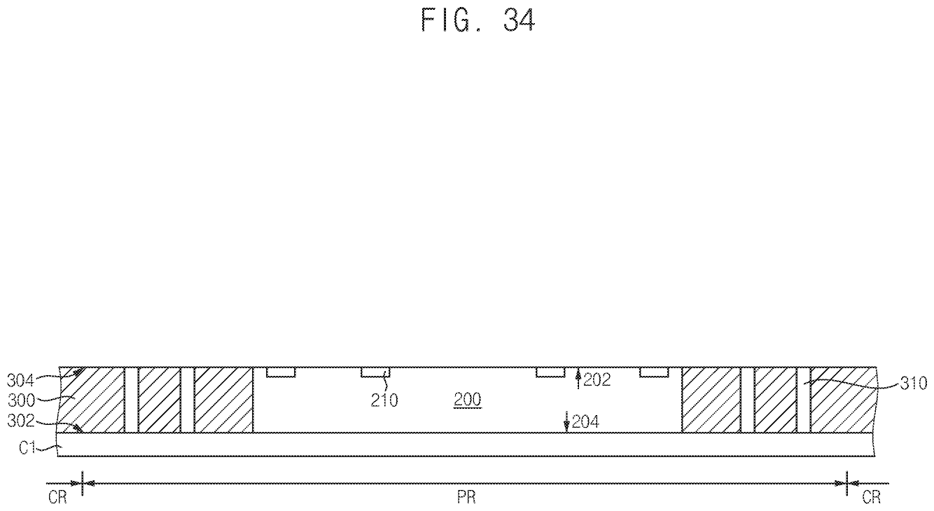

Referring to FIGS. 33 and 34, a sealing material 30 may be formed on the first carrier substrate C1 to cover the semiconductor chip 200 and the plurality of through vias 310, and an upper portion of the sealing material 30 may be partially removed to form a sealing member 300 that exposes the front surface 202 of the semiconductor chip 200 and upper surfaces of the plurality of through vias 310.

The sealing material 30 may be formed to cover the front surface 202 of the semiconductor chip 200 and the upper surfaces of the plurality of through vias 310. For example, the sealing material 30 may include an epoxy molding compound (EMC).

The upper portion of the sealing material 30 may be partially removed by a grinding process. As the upper portion of the sealing material 30 is removed, the chip pads 210 on the front surface 202 of the semiconductor chip 200 and the plurality of through vias 310 may be exposed from a second surface 304 of the sealing member 300. The sealing member 300 may cover a side surface of the semiconductor chip 200.

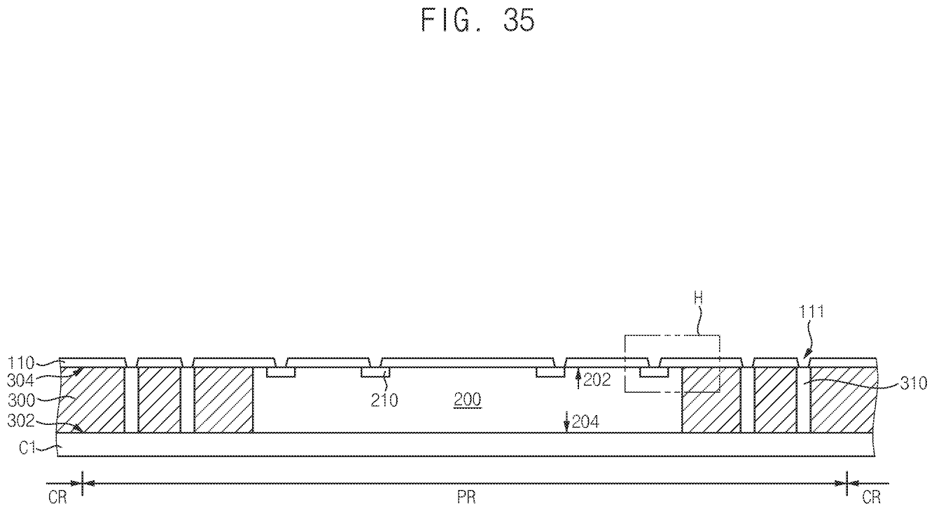

Referring to FIGS. 35 to 50, a lower redistribution wiring layer 100 having first redistribution wirings 102 may be formed on the second surface 304 of the sealing member 300 and the front surface 202 of the semiconductor chip 200.

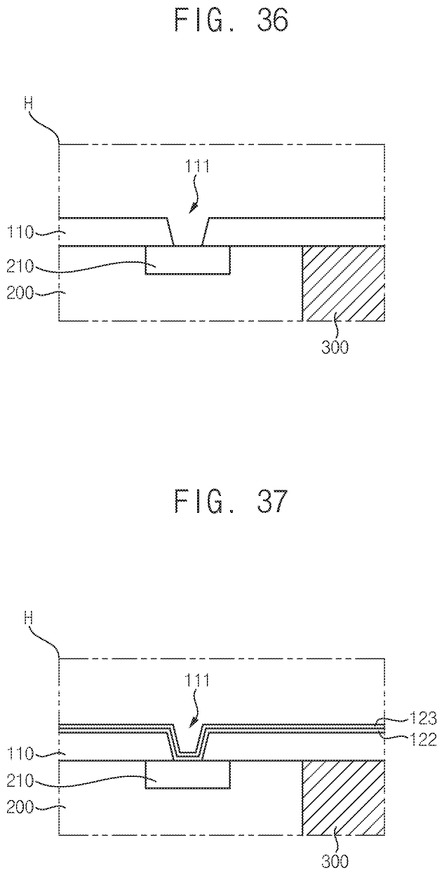

As illustrated in FIGS. 35 and 36, processes the same as or similar to the processes described with reference to FIGS. 6 and 7 may be performed to form a first lower insulating layer 110 on the second surface 304 of the sealing member 300 and the front surface of the semiconductor chip 200 and then, the first lower insulating layer 110 may be patterned to form first openings 111 that expose the through vias 310 and chip pads 210 respectively.

As illustrated in FIG. 37, a barrier layer 122 and a seed layer 123 may be sequentially formed on the first lower insulating layer 110. The barrier layer 122 is formed on sidewalls of the first openings 111 of the first lower insulating layer 110 and portions of the through vias 310 and the chip pads 210 exposed by the first openings 111.

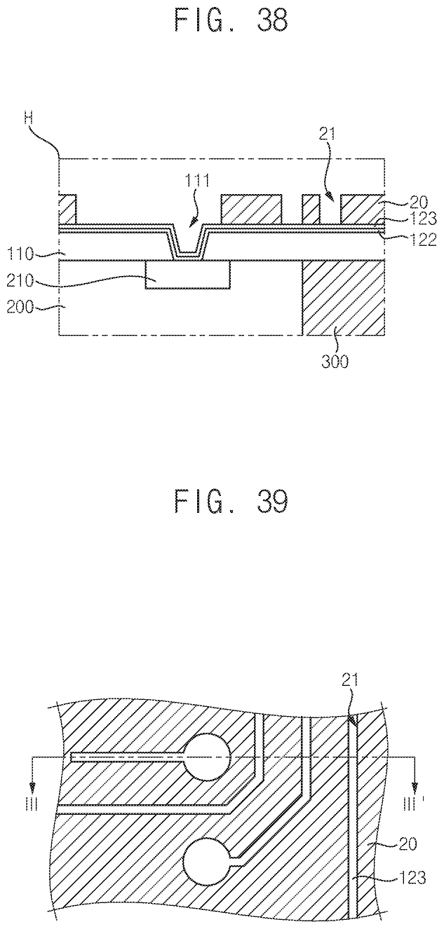

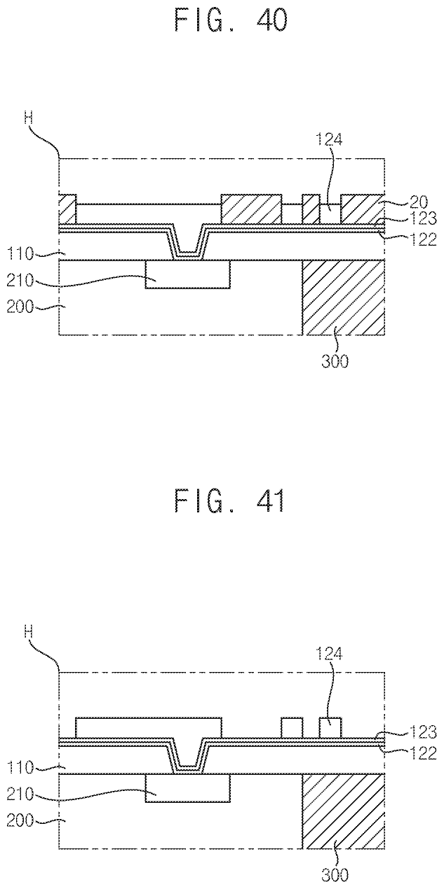

As illustrated in FIGS. 38 and 39, a photoresist layer may be formed on the seed layer 123, and an exposure process and a development process may be performed on the photoresist layer to form a photoresist pattern 20 having an opening(s) 21 that exposes a first lower redistribution region.

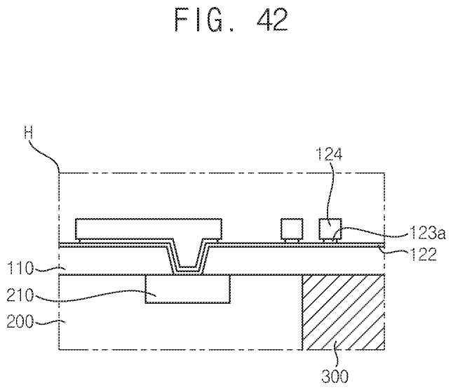

As illustrated in FIGS. 40 and 41, a first plating pattern 124 may be formed in the opening 21 of the photoresist pattern 20, and the photoresist pattern 20 may be removed from the first lower insulating layer 110. The first plating pattern 124 may be formed by an electroplating process or an electroless plating process.

As illustrated in FIG. 42, a portion of the seed layer 123 exposed by the first plating pattern 124 may be removed to form a first seed layer pattern 123a. The portion of the seed layer 123 exposed by the first plating pattern 124 may be removed by an isotropic etching process. The portion of the seed layer 123 may be removed by a wet etching process.

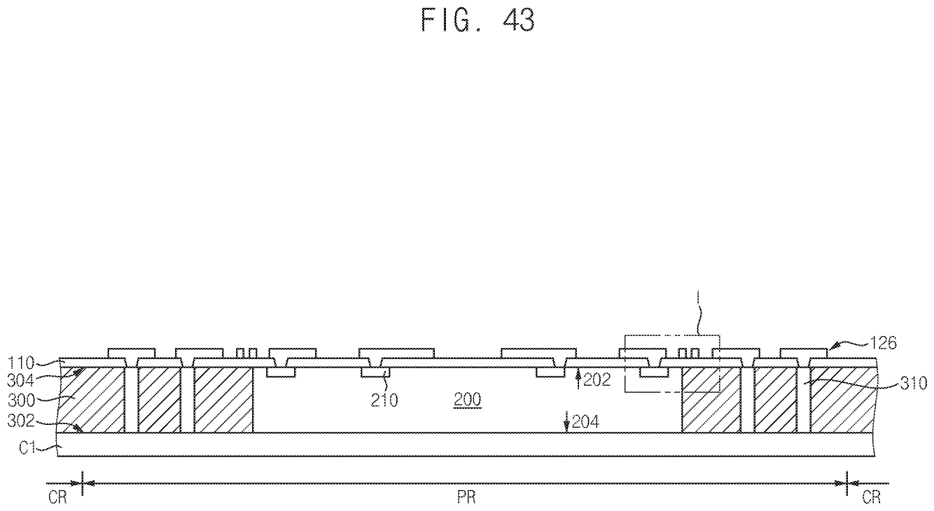

As illustrated in FIGS. 43 to 45, a portion of the barrier layer 122 exposed by the first seed layer pattern 123a may be removed to form a first barrier layer pattern 122a. The portion of the barrier layer 122 exposed by the first plating pattern 124 may be removed by an anisotropic etching process. The portion of the barrier layer 122 may be removed by a dry etching process.

Since the portion of the barrier layer 122 is removed by an anisotropic etching process, the portion of the barrier layer 122 exposed from an outer surface of the first plating pattern 124 may be removed. Accordingly, the sidewall of the first barrier layer pattern 122a may be positioned on substantially the same vertical plane as the sidewall of the first plating pattern 124. The sidewall of the first barrier layer pattern 122a may be positioned outside a sidewall of the first seed layer pattern 123a. In other words for example, the sidewall of the first barrier layer pattern 122a may extend laterally beyond the sidewall of the first seed layer pattern 123a. The sidewall of the first seed layer pattern 123a may form a recess recessed from the sidewall of the first plating pattern 124 and the sidewall of the first barrier layer pattern 122a.

Thus, the first lower redistribution wiring 126 including the first barrier layer pattern 122a, the first seed layer pattern 123a and the first plating pattern 124 may be formed on the first lower insulating layer 110. The first lower redistribution wirings 126 may be electrically connected to the chip pads 210 and the through vias 310 through the first openings 111 of the first lower insulating layer 110.

The first lower redistribution wiring 126 may include a first redistribution via 126a, a first redistribution line 126b and a first redistribution pad 126c. The first redistribution via 126a may be formed to penetrate the first lower insulating layer 110. The first redistribution line 126b may extend on the first lower insulating layer 110.

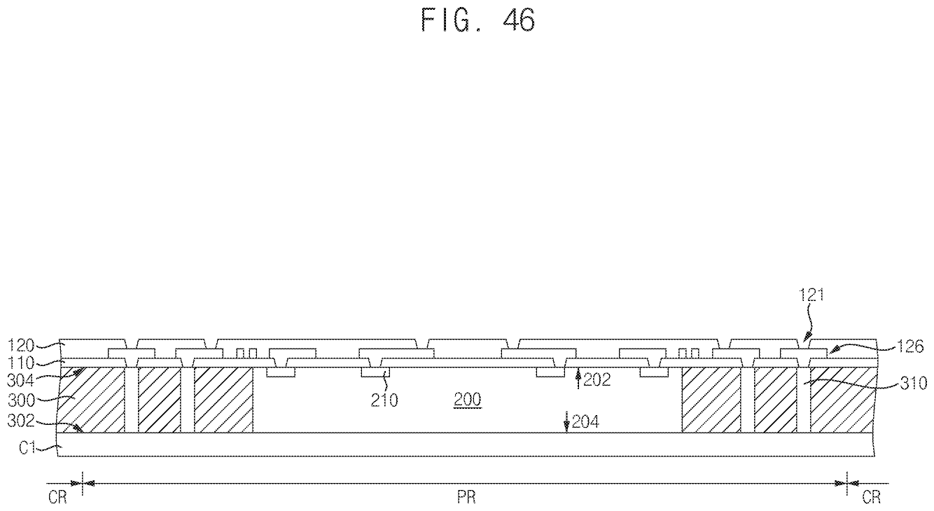

As illustrated in FIG. 46, processes the same as or similar to the processes described with reference to FIGS. 6 and 7 may be performed to form a second lower insulating layer 120 to cover the first lower redistribution wirings 126 on the first lower insulating layer 110 and to pattern the second lower insulating layer 120 to form second openings 121 that expose at least portions of the first lower redistribution wirings 126.

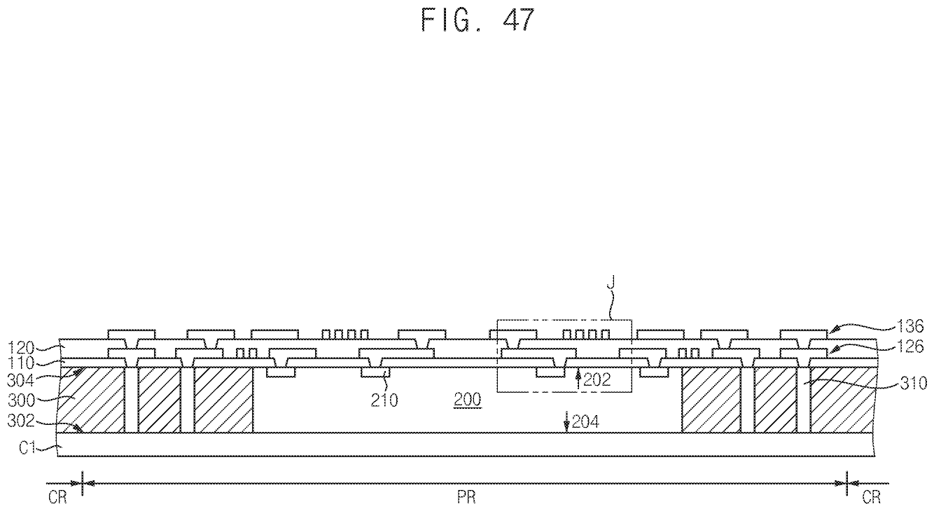

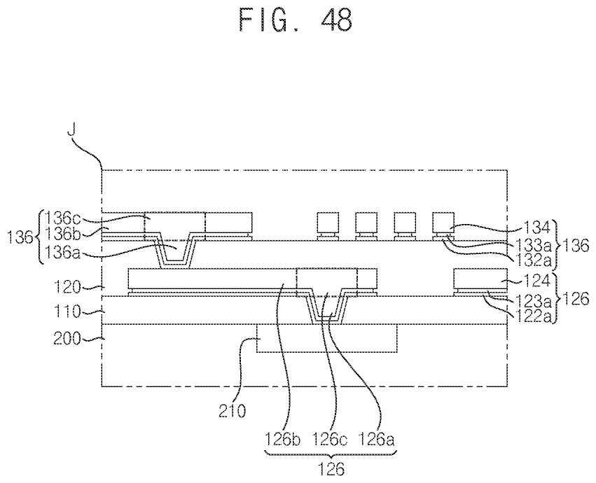

As illustrated in FIGS. 47 and 48, processes the same as or similar to the processes described with reference to FIGS. 8 to 16 may be performed to form second lower redistribution wirings 136 on the second lower insulating layer 120.

For example, a barrier layer and a seed layer may be sequentially formed on the second lower insulating layer 120, and a photoresist pattern having an opening that exposes a second lower redistribution region may be formed on the seed layer. Then, a second plating pattern 134 may be formed in the opening of the photoresist pattern by a plating process, and the photoresist pattern may be removed from the second lower insulating layer 120.

Then, a portion of the seed layer exposed by the second plating pattern 134 may be removed to form a second seed layer pattern 133a. The portion of the seed layer exposed by the second plating pattern 134 may be removed by an isotropic etching process. The portion of the seed layer may be removed by a wet etching process.

Then, a portion of the barrier layer exposed by the second seed layer pattern 133a may be removed to form a second barrier layer pattern 132a. The portion of the barrier layer exposed by the second seed layer pattern 133a may be removed by an anisotropic etching process. The portion of the barrier layer may be removed by a dry etching process.

Thus, the second lower redistribution wiring 136 including the second barrier layer pattern 132a, the second seed layer pattern 133a and the second plating pattern 134 may be formed on the second lower insulating layer 120. The second lower redistribution wiring 136 may be electrically connected to the first lower redistribution wiring 126 through the second opening 121 of the second lower insulating layer 120.

The second lower redistribution wiring 136 may include a second redistribution via 136a, a second redistribution line 136b and a second redistribution pad 136c. The second redistribution via 136a may be formed to penetrate the second lower insulating layer 120. The second redistribution line 136b may extend on the second lower insulating layer 120. The second barrier layer pattern 132a, the second seed layer pattern 133a and the second plating pattern 134 of the second lower redistribution wiring 136 may have widths and thicknesses the same as or similar to those of the first barrier layer pattern 122a, the first seed pattern 123a and the first plating pattern 124 of the first lower redistribution wiring 126.

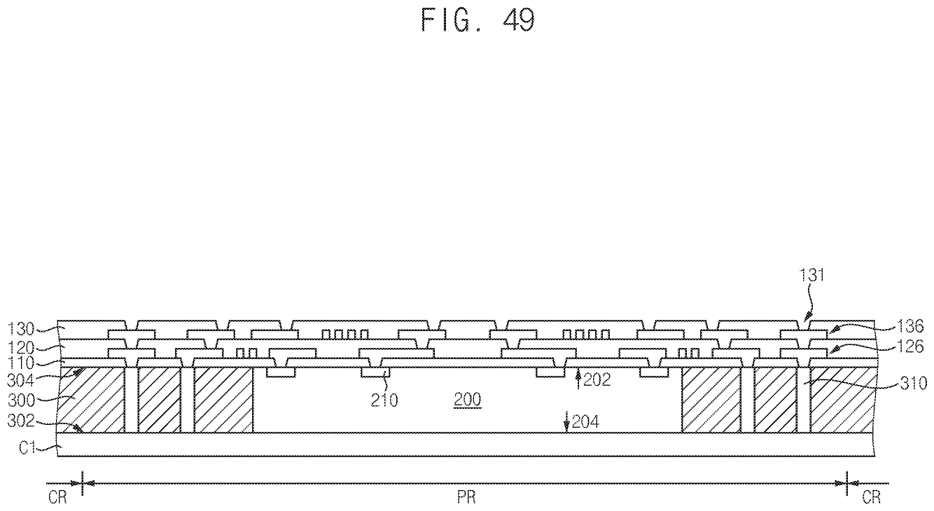

As illustrated in FIG. 49, processes the same as or similar to the processes described with reference to FIGS. 6 and 7 may be performed to form a third lower insulating layer 130 on the second lower insulating layer 120 to cover the second lower redistribution wirings 136 and to pattern the third lower insulating layer 130 to form third openings 131 that expose at least portions of the second lower redistribution wirings 136.

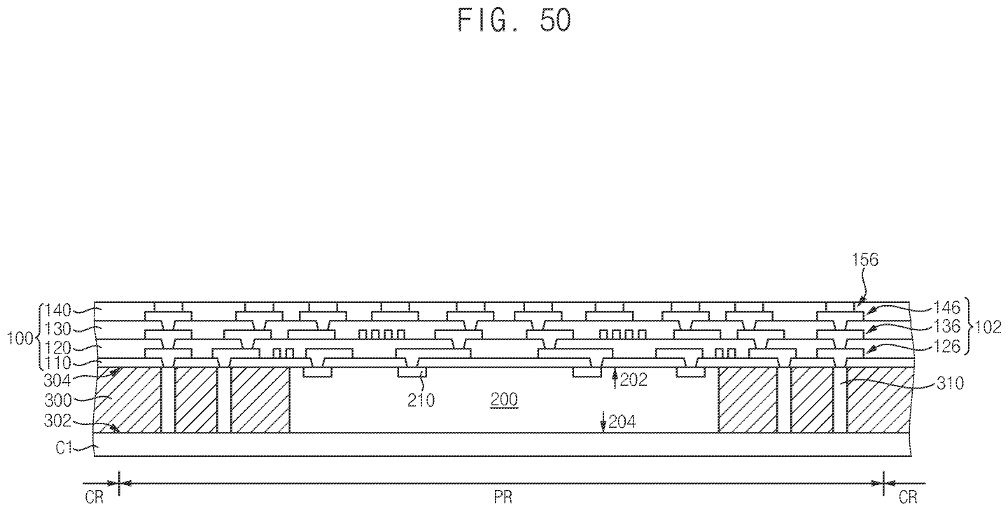

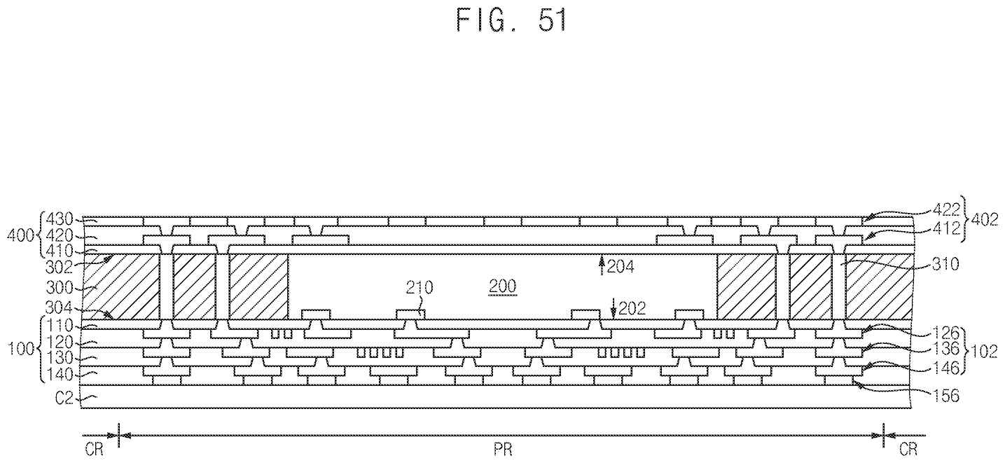

As illustrated in FIGS. 50 and 51, processes the same as or similar to the processes described with reference to FIGS. 8 to 16 may be performed to form third lower redistribution wirings 146 on the third lower insulating layer 130. Then, second bonding pads 156 may be formed on the third lower redistribution wirings 146.

Thus, the third lower redistribution wiring 146 including a third barrier layer pattern, a third seed layer pattern and a third plating pattern may be formed on the third lower insulating layer 130. The third lower redistribution wiring 146 may be electrically connected to the second lower redistribution wiring 136 through the third opening 131 of the third lower insulating layer 130.

The third lower redistribution wiring 146 may include a third redistribution via, a third redistribution line and a third redistribution pad. The third redistribution via may be formed to penetrate the third lower insulating layer 130. The third redistribution line may extend on the third lower insulating layer 130.

The third barrier layer pattern, the third seed layer pattern and the third plating pattern of the third lower redistribution wiring 146 may have widths and thicknesses the same as or similar to those of the first barrier layer pattern 122a, the first seed layer pattern 123a and the first plating pattern 124 of the first lower redistribution wiring 126.

Then, processes the same as or similar to the processes described with reference to FIGS. 8 to 16 may be performed to form second bonding pads 156 on the third lower redistribution wirings 146.

The second bonding pad 156 including a fourth barrier layer pattern, a fourth seed layer pattern and a fourth plating pattern may be formed on the third lower redistribution wiring 146. The second bonding pad 156 may be a bump pad. The bump pad may include a solder pad or a pillar pad.

Then, a solder resist layer 140 as a fourth lower insulating layer may be formed on the third lower insulating layer 130 to cover the third lower redistribution wirings 146 and expose at least a portion of the second bonding pad 156.

Referring to FIG. 51, processes the same as or similar to the processes described with reference to FIG. 27 may be performed to form an upper redistribution wiring layer 400 having second redistribution wirings 402 electrically connected to the through vias 310 on the upper surface 302 of the sealing member 300 and also having the first upper insulating layer 410, the second upper insulating layer 420 and the third upper insulating layer 430.

In particular, the second redistribution wirings 402 may include a first upper redistribution wiring 412 and a second upper redistribution wiring 422 stacked in two layers. In this case, the second upper redistribution wiring 422 may correspond to the uppermost redistribution wiring among the second redistribution wirings.

Then, upper bonding pads (not illustrated) are formed on the second upper redistribution wirings 422 as the uppermost redistribution wirings, respectively, and the third upper insulating layer 430 may be formed on the second upper insulating layer 420 to expose at least portions of the upper bonding pads. The third upper insulating layer 430 may serve as a passivation layer.

Then, external connection members 500 (see FIG. 29) may be formed on an outer surface, (i.e., a lower surface), of the lower redistribution wiring layer 100 to be electrically connected to the first redistribution wirings 102.

Then, a sawing process may be perform to individualize the lower redistribution wiring layer 100, to complete a fan out wafer level package 12 of FIG. 29 including the sealing member 300, the lower redistribution wiring layer 100 formed on the lower surface 304 of the sealing member 300 and the upper redistribution wiring layer 400 formed on the upper surface 302 of the sealing member 300.

The semiconductor package may include semiconductor devices such as logic devices or memory devices. The semiconductor package may include logic devices such as for example central processing units (CPUs), main processing units (MPUs), or application processors (APs), or the like, and volatile memory devices such as for example DRAM devices, HBM devices, or non-volatile memory devices such as for example flash memory devices, PRAM devices, MRAM devices, ReRAM devices, or the like.

The foregoing is illustrative of example embodiments and should not to be construed as limiting thereof. Although a few example embodiments have been described, those skilled in the art should readily appreciate that many modifications are possible in example embodiments without materially departing from the novel teachings and advantages of the inventive concepts. Accordingly, all such modifications are intended to be included within the scope of example embodiments as defined in the claims.

What is claimed is:

1. A semiconductor package, comprising:
a lower redistribution wiring layer having first redistribution wirings stacked in at least two layers;
a semiconductor chip on the lower redistribution wiring layer and electrically connected to the first redistribution wirings;
a sealing member covering the semiconductor chip on the lower redistribution wiring layer;
a plurality of through vias penetrating the sealing member and electrically connected to the first redistribution wirings; and
an upper redistribution wiring layer on the sealing member and having second redistribution wirings electrically connected to the plurality of through vias,
wherein each of the first redistribution wirings includes a barrier layer pattern, a seed layer pattern and a plating pattern sequentially stacked, and
viewed from a plan view, a sidewall of the barrier layer pattern extends laterally beyond a sidewall of the seed layer pattern.

2. The semiconductor package of claim 1, wherein the each of the first redistribution wirings includes a recess configured by the sidewall of the seed layer pattern recessed from a sidewall of the plating pattern and the sidewall of the barrier layer pattern.

3. The semiconductor package of claim 1, wherein the sidewall of the barrier layer pattern and ae sidewall of the plating pattern are vertically aligned with each other.

4. The semiconductor package of claim 1, wherein the barrier layer pattern has a first thickness, the seed layer pattern has a second thickness, and the plating pattern has a third thickness greater than the first thickness and greater than the second thickness.

5. The semiconductor package of claim 4, wherein the third thickness of the plating pattern is within a range of 2 μm to 10 μm.

6. The semiconductor package of claim 1, wherein the each of the first redistribution wirings includes a redistribution via penetrating an underlying insulating layer, a redistribution pad on the redistribution via, and a redistribution line extending from the redistribution pad on the underlying insulating layer.

7. The semiconductor package of claim 6, wherein the redistribution line has a width of 3 μm or less.

8. The semiconductor package of claim 1, wherein the semiconductor chip is mounted on the lower redistribution wiring layer via conductive bumps.

9. The semiconductor package of claim 1, wherein the sealing member exposes an upper surface of the semiconductor chip.

10. The semiconductor package of claim 1, further comprising:
a second package on the upper redistribution wiring layer,
wherein the second package comprises a package substrate and at least one second semiconductor chip stacked on the package substrate.

11. A semiconductor package, comprising:
a lower redistribution wiring layer having first redistribution wirings stacked in at least two layers;
a semiconductor chip on the lower redistribution wiring layer, the semiconductor chip having a first surface with chip pads on the first surface, and the first surface facing the lower redistribution wiring layer;
a sealing member covering the semiconductor chip on the lower redistribution wiring layer;
a plurality of through vias penetrating the sealing member and electrically connected to the first redistribution wirings; and
an upper redistribution wiring layer on the sealing member,
wherein each of the first redistribution wirings includes a barrier layer pattern, a seed layer pattern and a plating pattern sequentially stacked on one another, and
viewed from a plan view, a sidewall of the barrier layer pattern extends laterally beyond a sidewall of the seed layer pattern.

12. The semiconductor package of claim 11, wherein the each of the first redistribution wirings includes a recess configured by the sidewall of the seed layer pattern recessed from a sidewall of the plating pattern and the sidewall of the barrier layer pattern.

13. The semiconductor package of claim 12, wherein the sidewall of the barrier layer pattern and the sidewall of the plating pattern are vertically aligned with each other.

14. The semiconductor package of claim 11, wherein the barrier layer pattern has a first thickness, the seed layer pattern has a second thickness, and the plating pattern has a third thickness greater than the first thickness and greater than the second thickness.

15. The semiconductor package of claim 14, wherein the third thickness of the plating pattern is within a range of 2 μm to 10 μm.

16. The semiconductor package of claim 11, wherein the each of the first redistribution wirings comprises a redistribution via penetrating an underlying insulating layer, a redistribution pad on the redistribution via, and a redistribution line extending from the redistribution pad on the underlying insulating layer.

17. The semiconductor package of claim 16, wherein the redistribution line has a width of 3 μm or less.

18. The semiconductor package of claim 11, wherein the barrier layer pattern comprises titanium, and the seed layer pattern comprises copper.

19. The semiconductor package of claim 11, further comprising:
a second package on the upper redistribution wiring layer,
wherein the second package comprises a package substrate and at least one second semiconductor chip stacked on the package substrate.

20. A semiconductor package, comprising:
a lower redistribution wiring layer having first redistribution wirings stacked in at least two layers;
a semiconductor chip on the lower redistribution wiring layer and electrically connected to the first redistribution wirings;
a sealing member covering the semiconductor chip on the lower redistribution wiring layer;
a plurality of through vias penetrating the sealing member and electrically connected to the first redistribution wirings; and
an upper redistribution wiring layer on the sealing member,
wherein each of the first redistribution wirings includes a redistribution via penetrating an underlying insulating layer, a redistribution pad on the redistribution via, and a redistribution line extending from the redistribution pad on the underlying insulating layer,
wherein the redistribution line includes a barrier layer pattern, a seed layer pattern and a plating pattern sequentially stacked on the underlying insulating layer, and
wherein the redistribution line includes a recess configured by a sidewall of the seed layer pattern recessed from a sidewall of the plating pattern and a sidewall of the barrier layer pattern.
